(19) United States
(12) Patent Application Publication
(10) Pub. No.: US 2012/0304931 A1
(43) Pub. Date: Dec. 6, 2012

(54) Carbon-Based Containment System

(75) Inventors: Cayan BAGATUR, Greenville, SC (US); Steven COPPELLA, Greenville, SC (US); Steven GAUDREAU, Greenville, SC (US); Andrew GOSHE, Greenville, SC (US); James Alan SNIPES, Greenville, SC (US)

(73) Assignee: Morgan Advanced Material and Technology, Inc., St. Marys, PA (US)

(21) Appl. No.: 13/586,151

(22) Filed: Aug. 15, 2012

Related U.S. Application Data
(63) Continuation of application No. PCT/US2011/026147, filed on Feb. 25, 2011.
(60) Provisional application No. 61/308,451, filed on Feb. 26, 2010.
(60) Provisional application No. 61/436,268, filed on Jan. 26, 2011.

(51) Int. Cl. B01J 19/00; F16B 5/06; C23C 16/00

(52) U.S. Cl. 118/715; 403/205; 422/310; 422/241

(57) ABSTRACT

A containment system, for instance, for containment of heat and/or chemical gases, is described, for instance, carbon-based containment systems that can include an insulation segment, a shield segment, and/or a divider segment, wherein each can be a plurality of panels, such as wall panels, that form walls.

This application is a continuation of International Patent Application No. PCT/US2011/026147, filed Feb. 25, 2011, which claims the benefit under 35 U.S.C. §119(e) of prior U.S. Provisional Patent Application No. 61/308,451, filed Feb. 26, 2010 and prior U.S. Provisional Patent Application No. 61/436,268 filed Jan. 26, 2011, which are incorporated in their entirety by reference herein.

### BACKGROUND OF THE INVENTION

The present invention relates to containment systems, for instance, for containment of heat and/or chemical gases and the like. More particularly, the present invention relates to carbon-based containment systems that can be used, for instance, in a reactor or furnace, and which can provide insulation and/or shielding from heat, chemicals, and the like. The containment system(s) can provide a full or partial enclosure by forming panels or walls around the reactor or furnace.

The present invention further relates to the field of carbon-based insulation and/or shielding materials. More particularly the use thereof in an apparatus for use in the production of semiconductor materials, and is particularly although not exclusively applicable to the production of polycrystalline silicon by chemical vapour deposition and silicon ingot production by recrystallization processes.

Carbon-fiber-based insulation products can be formed from carbon fiber precursors. Carbon fiber precursors include, but are not limited to rayon, acrylic (polyacrylonitrile (PAN)), petroleum-based pitch, coal tar-based pitch as well as other carbon precursor materials. Traditionally, felt insulation is produced by carbonizing/graphitizing a needled, nonwoven blanket of the carbon precursor fibers, thus not requiring the addition of resin binders. The resulting felt insulation has good insulating properties. A drawback to the use of felt insulation alone is that the felt insulation is soft and pliable and has little structural form.

Rigid board insulation is commonly produced by chopping carbonized fiber into short lengths. The chopped fibers are then slurried with a phenolic or similar resin. The slurry is formed into blocks, thermally processed, and further formed into boards or other forms. The resulting rigid board insulation has good structural strength and stiffness.

Rigidized-felt board insulation is commonly produced by layering carbonized or graphitized felt and impregnating with a phenolic or similar resin. The layup is thermally processed and further formed into boards or other forms.

Carbon and graphite materials are commonly produced from mixtures of fillers and binders. Filler materials include but are not limited to petroleum coke, pitch coke, metallurgical coke, carbon blacks, and natural graphite particles. Binder materials include but are not limited to coal tar pitch, petroleum pitch, phenolic and other resins, coal tars and oils, and petroleum tars and oils. These are intimately mixed and formed by extrusion, uniaxial pressing, or isostatically pressing. These are then subjected to thermal treatments to achieve the carbon or graphite material.

In applications such as the production of high purity semiconductor material, high purity raw materials are used. For example, high purity polycrystalline silicon is used as a raw material in the fabrication of single crystal silicon in the semiconductor industry. Commonly known processes in the art for the production of single crystal silicon are the CZ (Czochraslski) process, DSS (Directional Solidification Systems) process and the FZ (Float Zone) process. The raw material or feedstock used in the above processes is traditionally manufactured by Chemical Vapour Deposition from a precursor compound of the semiconductor material. In the case of silicon production, the precursor gas is typically a silane such as trichlorosilane or silane.

There are two basic apparatuses, for the production of high purity polycrystalline silicon. These are a Chemical Vapour Deposition (CVD) Reactor and a Thermal Convertor.

The CVD Reactor produces silicon from the precursor gases. The Thermal Convertor re-cycles the by-products of the CVD reaction process into a useful precursor gas for feeding back into the CVD reactor, thereby reducing waste.

The most common CVD process, involves hydrogen reduction of a trihalosilane, particularly trichlorosilane, HSiCl₃, to silicon according to the simplified reversible reaction:

HSiCl₃+H₂ [symbol] Si(s)+by-products

The reaction is carried out at an elevated temperature by mixing the gases and bringing them into contact with a heated filament deposition surface. Other precursor gases include various silanes, particularly, SiH₄, which decomposes at elevated temperatures of about 800° C. to silicon.

A commonly known CVD reactor is that used in the Siemens process described in EP1257684 (GT Solar Inc.). This reactor includes a base plate, a vessel forming a reaction chamber, and a heater. The base plate comprises a plurality of feed through holes for electrical connections to high purity silicon rods, called “slim rods” or filaments. These rods are heated through electrical resistance, although due to the high electrical resistance of silicon, external heaters are used to raise the temperature of these high purity rods to approximately 400° C. in order to reduce their electrical resistivity. In order to accelerate the heating process, a very high voltage, in the order of thousands of volts, is applied to the rods. The initial current flowing in the rods generates heat in the rods, reducing their electrical resistance and permitting higher current to flow and more heat. During the CVD process, polysilicon accumulates uniformly on the slim rods. The present invention is not limited to such a process, but is applicable to any process for the thermal decomposition of precursor gases to form solids in a reactor.

During the CVD process, a large proportion of the precursor gases such as trichlorosilane is not reduced to silicon but is converted to a number of ‘by-products’ or exhaust gases such as chlorosilane, e.g. SiCl₄, SiH₂Cl₂, SiHCl, SiCl₂ and silane polymers. The exhaust gases or ‘by-products’ from the CVD reaction are treated to reclaim the useful gases which are recycled back through the reactor.

Critical to the quality of the chemically vapour deposited product is the purity of the product. In systems for the chemical vapour deposition of silicon, the critical contaminants that influence the purity of the polysilicon product are carbon, oxygen, the Group III (boron, aluminium, gallium, indium, thallium), particularly boron, Group V elements (nitrogen, phosphorus, arsenic, antimony, bismuth), particularly phosphorus, and transition metals including but not limited to iron, chromium, nickel, copper, and zinc. These impurities may be introduced into the polysilicon product by their presence in the reaction and by-product gasses in the system or by gradual evolvement from the materials used in the design and construction of the reactor and thermal convertor, including the carbon and graphite components.

In the Siemens process, silicon tetrachloride, SiCl₄, is reacted with excess hydrogen at high temperatures (usually 1400° C.) to recover useful silicon trichlorosilane, HSiCl₃, for the CVD process. Other recovery processes include the Texas Instruments and Motorola two stage process.

The Texas Instruments process (U.S. Pat. No. 4,117,094 (Blocher, J); U.S. Pat. No. 4,213,937 (Fowler, J. H); U.S. Pat. No. 4,092,446 (Padovani, F. A); and U.S. Pat. No. 3,020,128 (Adcock, W. A)) involves a two stage reaction of silicon tetracholoride, metallurgical grade silicon, hydrogen and hydrogen chloride to produce trichlorosilane. Hydrogen is added in the first stage with temperatures at 1327° C. and hydrogen chloride is added in the second stage with temperatures at 800° C.

The Motorola process (U.S. Pat. No. 4,491,604 (Lesk, I. A) and U.S. Pat. No. 4,321,246 (Sarma, K. R)) is similar to the Texas Instruments process, with lower temperatures, but uses a copper catalyst and generates large amounts of dichlorosilane. Dichlorosilane can be disproportionated with silicon tetrachloride to form trichlorosilane. Alternatively, dichlorosilane can also be treated with metallurgical grade silicon and hydrogen chloride to form trichlorosilane.

Another process involves hydrochlorination of silicon tetracholoride to silicon tricholorosilane. In this process, tricholorosilane is produced by the reaction of silicon tetracholoride, metallurgical grade silicon and hydrogen at about 500° C. and 500 psi according to the reaction:

Si_{(metallurgical grade)}+2H₂+2SiCl₄ [symbol] 4 HSiCl₃

Small particles of metallurgical grade silicon are fluidized with hydrogen in a fluid bed to maximize the reaction rate.

A thermal convertor typically comprises a gas distribution system for the efficient mixing of the exhaust gases, internal heater rods, a gas venting system, and a baseplate comprising a plurality of holes for accommodating the heater rods, all being housed in an outer steel vessel. The thermal convertor transforms the ‘by-products’ or exhaust gases such as chlorosilane, e.g. SiCl₄, SiH₂Cl₂, SiHCl, SiCl₂ and silane polymers by chemical reaction into useful trichlorosilane. The process of the chemical reaction is influenced by the temperature of the operation.

The corrosive nature of the exhaust gases and their by-products such as chlorosilanes and hydrogen chloride gas formed or introduced during the thermal conversion process has meant that inert materials such as carbon-based materials, including carbon, graphite, carbon fibre composites and the like are typically used inside the convertor as heat insulating materials, for the base plate, as heating elements and for the containment of the exhaust gasses in the conversion chamber. While carbon materials are relatively inert to chlorosilanes and hydrogen chloride reaction, they are susceptible to chemical reaction and degradation by hydrogen, silicon oxides, and oxygen. The chemical reaction of the carbon materials with hydrogen generates methane gas. The chemical reaction of carbon materials with silicon oxides converts the surface of the carbon to silicon carbide and generates carbon monoxide and carbon dioxide gas. The chemical reaction of carbon materials with oxygen generates carbon monoxide and carbon dioxide gas. The carbonaceous gaseous by-products from these reactions can contaminate the produced polysilicon material, substantially reducing their value.

Heat is generated during the thermal conversion process which is absorbed by the outer vessel of the reaction chamber. It is possible to operate thermal conversion processes without insulation. In this case, all of the generated heat is transferred to process cooling water in the outer shell. The deficiencies of this type of operations are reduced chemical conversion of the by-product gasses to trichlorosilane, and increased energy use to maintain the temperature of the reaction vessel. The reaction zone of the vessel may also use insulation that both limits the heat loss, reducing energy use, and enables higher temperature operation of the thermal convertor, enabling higher conversion efficiencies. The insulation cooperates with the base plate to form a conversion chamber.

To overcome heat loss in the thermal conversion process, prior art insulation systems typically consist of a cylindrically shaped carbon-based body which cooperates with the base plate to form the conversion chamber. In the case of the CVD Reactors, the outer steel vessel housing a reaction chamber tends to be water cooled to prevent excess heat from damaging the steel vessel.

In addition to providing thermal insulation, the carbon insulation body should also possess sufficient structural integrity and strength to maintain its shape at the high reaction temperatures. In the case of the base plate, the material forming the base plate should not only possess insulation properties to inhibit excessive heat loss but also have sufficient structural strength to support the gas distribution system in the case of thermal convertors. To provide the structural integrity, the carbon insulation and the base plates are each integrally formed as single bodies. Fabricating such single bodies requires extensive forming and machining operations with consequent cost. Forming operations include, but are not limited to, isostatically pressing, uni-axial pressing, moulding, casting, etc. Moreover, the weight and size of the insulation liner means that it suffers from handling problems and mechanical hoists are needed to lower the insulation body onto the base plate. Additionally, the carbon insulation body is susceptible to mechanical damage during assembly and disassembly operations. If any one part of the insulation body degrades, it is necessary to replace the entire body.

Further, the carbon insulation body should also possess sufficient chemical inertness so as to persist in environments containing hydrogen, silicon oxides, and low levels of oxygen. Despite being relatively inert, the carbon-based material will eventually degrade over time, for example through reaction with hydrogen to form methane, through reaction with oxygen to form carbon dioxide, or the reaction with the silicon oxides to form silicon carbide and carbon dioxide.

Insulation/shielding bodies are thus needed that possess superior thermal insulation properties but yet have sufficient rigidity for use in applications, for example in the production of semiconductor materials. A need exists for a containment system that:
can provide sufficient thermal insulation for a thermally controlled gas phase chemical process such as chemical vapour deposition reaction process or conversion process described above in the production of semiconductor materials (for example polycrystalline silicon) or for a thermally controlled liquid-to-solid phase physical process such as crystal growth processes (for example silicon ingot growth by the Czochraslski or directional solid solidification processes).
has sufficient structural integrity to maintain their shape at high temperatures
is easier to handle and assemble than conventional insulation bodies
does not necessitate replacing the entire insulation system if any one area of insulation degrades or is damaged; and
provides protection against the harsh chemical environment.

Accordingly, the present invention addresses one or more of the above-identified problems and/or disadvantages.

### SUMMARY OF THE PRESENT INVENTION

A feature of the present invention is to provide a containment system, for instance, for a reactor (such as described above) that enables sustainable higher temperatures of operation, for instance, at least sustainable operations for at least one week at 1300° C.

A further feature of the present invention is to provide a containment system or portion thereof that is easier to handle and assemble than conventional containment systems or insulation systems.

An additional feature of the present invention is to provide a containment system or portion thereof that does not necessitate replacing the entire containment system if one portion is damaged or degrades.

An additional feature of the present invention is to provide a containment system, for instance, for a reactor, that provides improved insulation properties and/or improved shielding properties compared to conventional insulation structures.

An additional feature of the present invention is to provide a containment system that can be erected without the use of a crane and, further, can be dismantled or repaired without the use of a crane or other lifting device.

Additional features and advantages of the present invention will be set forth in part in the description that follows, and in part will be apparent from the description, or may be learned by practice of the present invention. The objectives and other advantages of the present invention will be realized and attained by means of the elements and combinations particularly pointed out in the description and appended claims.

To achieve these and other advantages, and in accordance with the purposes of the present invention, as embodied and broadly described herein, the present invention relates to a carbon-based containment system, for instance, for a reactor or furnace. The carbon-based containment system can comprise:
a) an insulation segment that comprises at least one insulation layer; and/or
b) a shield segment that comprises at least one shield layer,
   wherein the at least one insulation layer comprises a carbonaceous material or carbon-based material (e.g., in a predominate amount), and the at least one shield layer comprises a carbonaceous material or carbon-based material (e.g., in a predominant amount). Further details are provided below and in the drawings. The containment system can form a wall or series of walls that surround a reactor or furnace and the containment system can be a plurality of panels (e.g. wall panels or sections thereof) that form the wall(s), optionally with a lid and/or base. A segment for purposes of the present invention can be a portion of the containment system, a component of the containment system, or a division of the containment system. Each segment of the containment system can comprise one or more pieces or panels.

The present invention further relates to or can include a divider segment that can optionally be used along with the insulation segment and/or shield segment, wherein the divider segment comprises at least one divider layer that, for instance, can be a carbonaceous material or carbon-based material (e.g., in a predominant amount). The divider segment can be a plurality of panels (e.g., wall panels or sections thereof) that form a wall or a series of interconnecting walls within the insulation and/or shield segments.

The present invention further relates to a containment system that can comprise an insulation segment that comprises a plurality of insulation panels that optionally removably interlock together, and/or a shield segment that comprises a plurality of shield panels, and/or a divider segment that comprises a plurality of divider panels, wherein any one or all of the insulation segment, shield segment, and/or divider segment can removably interlock together and, further, wherein the insulation segment and shield segment can also optionally be removably interlocked together. The interlocking of the insulation panels, and/or shield panels, and/or divider panels can be accomplished through the use of interlocking features on the panels (e.g., tongue and groove, lips, protruding shoulders, and the like) and/or through the use of connectors, for instance, having the various designs described below and exemplary designs are shown in the drawings.

The present invention further relates to various insulation segments, shield segments, and/or divider segments that comprise or have various properties, such as physical properties and/or structural properties, that are quite beneficial to a carbon-based containment system and that provides suitable or improved insulation and/or shield properties as described herein.

It is to be understood that both the foregoing general description and the following detailed description are exemplary and explanatory only and are intended to provide a further explanation of the present invention, as claimed.

The accompanying drawings, which are incorporated in and constitute a part of this application, illustrate some of the features of the present invention and together with the description, serve to explain the principles of the present invention.

### BRIEF DESCRIPTION OF DRAWINGS

FIG. 1 is an exemplary view of an outer insulation segment comprising wall panels.

FIG. 2 is an exemplary view of an inner shield segment.

FIG. 3 is an exemplary break-away view of the system showing the outer insulation segment and inner shield segment.

FIG. 4 is an exemplary view of a single ring of the system showing the outer insulation, inner shield, and connectors.

FIG. 5 is an exemplary view of the lowest ring of the outer insulation, inner shield, connectors, and base plate.

FIG. 6 is an exemplary view of the outer insulation, inner shield, and connectors.

FIG. 7 is an exemplary view of the outer insulation and inner shield with connectors removed to show the junction between segments.

FIG. 8 is an exemplary view of a single panel of the outer insulation liner and inner shield with connectors at the corners showing assembly.

FIG. 9 is an exemplary view of a middle connector.

FIG. 10 is an exemplary view of a single panel of the inner shield.

FIG. 11 is an exemplary view of a top view of the outer insulation panels(s) showing means of connection.

FIG. 12 is an exemplary view of two panels of the outer insulation.

FIG. 13 is an exemplary view of the base plate showing the outer insulation and inner shield.

FIG. 14 is an exemplary view of a top or bottom connector.

FIG. 15 is an exemplary view of the connector fitting into the bottom shield.

FIG. 16 is an exemplary view of a channel created in a thermal convertor by divider plates.

FIG. 17 is an exemplary view of a front view of a channel created in a thermal convertor by divider plates.

FIG. 18 is an exemplary view of a channel divider plate and connector.

FIG. 19 is an exemplary view of a middle connector for divider plates.

FIG. 20 is an exemplary view of a channel divider plate showing inter-connection to the base plate.

FIG. 21 is an exemplary view of a top and bottom connector 110°-140° (18 ea).

FIG. 22 is an exemplary view of a bottom connector 105°-135° (3 ea).

FIG. 23 is an exemplary view of a bottom connector 110°-130° (3 ea).

FIG. 24 is an exemplary view of a middle connector 110°-140° (27 ea).

FIG. 25 is an exemplary view of a middle connector 110°-130° (9 ea).

FIG. 26 is an exemplary view of a middle connector 105°-135° (9 ea).

FIG. 27 is an exemplary view of a top connector 110°-130° (3 ea).

FIG. 28 is an exemplary view of a top connector 105°-135° (3 ea).

FIG. 29 is an exemplary view of a cut away view of a divider segment comprising a plurality of divider panels interconnected together on a base plate(s) with the use of connectors, such as three-panel type connectors.

FIG. 30 is an exemplary view of a connector that can be used to connect three panels together, such as shown in FIG. 29.

FIG. 31 is a top view of the connector of FIG. 30.

FIG. 32 is a perspective view of a layered insulation material formed from rigid and flexible layers, according to one embodiment of the present invention.

FIG. 33 is another perspective view of the layered insulation material formed from rigid, flexible, and graphite foil layers, according to another embodiment of the present invention.

FIG. 34 is a perspective view of a layered insulation material formed from rigid, flexible, and graphite paint layers, according to yet another embodiment of the present invention.

FIG. 35 is a perspective view of the layered insulation material formed from multiple rigid, flexible, and graphite foil layers, according to yet another embodiment of the present invention.

FIG. 36 is another perspective view of the layered insulation material formed from multiple rigid, flexible, and graphite paint layers, according to yet another embodiment of the present invention.

FIG. 37 is a schematic representation of the multiple rigid, flexible, and graphite paint layers of the layered insulation material of FIG. 35 or 36.

FIG. 38 is a perspective view showing an insulation liner according to an embodiment of the present invention.

FIG. 39 is a line drawing of the cylindrical shaped insulation liner body shown in FIG. 38.

FIG. 40 is a side perspective view of the cylindrical shaped insulation liner body shown in FIG. 39.

FIG. 41 shows a top view of the ring shaped insulation liner shown in FIG. 40.

FIG. 42 is an expanded view of the interlocking arrangement shown in FIG. 41.

FIG. 43 is a perspective view of one insulation sub-unit according to an embodiment of the invention.

FIG. 44 is a perspective view of a key used to interlocking adjacent sub-units together.

FIG. 45 is a perspective view of an insulation liner fabricated from an assembly of a plurality of interlocked units shown in FIG. 43.

FIG. 46 is a perspective view of the top lid of the insulation liner of FIG. 45.

FIG. 47 is a perspective view of the outer bell steel chamber surrounding the insulation liner of FIG. 45.

FIG. 48 is a plot showing a comparison of the thermal conductivity of the rigid-flexible hybrid insulation material according to an embodiment of the present invention and the thermal conductivity of the rigid board and flexible material.

### DETAILED DESCRIPTION OF THE PRESENT INVENTION

The present invention relates to a containment system for a reactor, furnace, or other device or system or process which requires containment of heat and/or chemicals. The present invention specifically relates to a carbon-based containment system which can have an insulation segment alone, a shield segment alone, or a combination of both. The use of an optional divider segment is further described below. Each segment can be a wall or a series of walls that can be formed by multiple wall panels for each segment.

As an example, the present invention relates to a carbon-based containment system that comprises:

a) an insulation segment, and/or

b) a shield segment.

The insulation segment, which can be or include the shape of a wall, can comprise at least one insulation layer. The insulation layer or layers can comprise a carbon fiber rigid board, a carbon fiber rigidized felt board, a carbon fiber flexible felt, a graphite fiber flexible felt, a carbon foam board, a carbon aerogel board, or any combination thereof. For example, the insulation segment can comprise multiple insulation layers that can be the same or different from each other with respect to the material, thickness, structural properties, and/or physical properties, and the like. For example, the insulation segment can comprise two or more insulation layers, and one of the insulation layers can be a carbon fiber rigid board and another insulation layer that forms the same insulation segment can be a flexible graphite felt. Any combination of different insulation layers can be used to form the insulation segment (e.g., wall panel(s)). When more than one insulation layer is used to form the insulation segment, the two or more insulation layers can be bonded or otherwise permanently or removably affixed together to form a composite. For instance, two or more insulation layers can be laminated together using a binder system by various techniques, such as applying heat and pressure to the insulation layers, such as a temperature of 100 degrees C. to 1,000 degrees C. Flexible insulation or other flexible material described herein as a part of the containment system is defined as any material or layer that can be bent around a 10 inch diameter form and still be usable as an insulating material in the case of the insulation segment, or still be usable as a shielding material in the case of the shielding segment. The flexible insulation material or layer, if used, may be formed from any appropriate carbon fiber precursor, including, but not limited to, Rayon, PAN, pitch, or other suitable carbon precursor material

The insulation segment that comprises at least one insulation layer can take the form of or comprise a plurality of insulation panels, such as wall panels or sections thereof. These insulation panels can have identical dimensions with respect to each other and be part of the same containment system, or, as an option, the insulation panels can have different dimensions. The insulation panels, as an option, can have the same materials that comprise each insulation panel, or, as an option, one or more insulation panels can contain a different insulation layer or layers from other one or more insulation panels.

The insulation segment, when comprising a plurality of insulation panels (e.g., wall panels) can have a panel design or structure that permits the interlocking of the insulation panels together, such as shown in some of the figures herein, to form a wall that can encircle a reactor or furnace. As shown, the panels can have a tongue and/or groove, or other interlocking feature that permits the mechanical locking of two panels together.

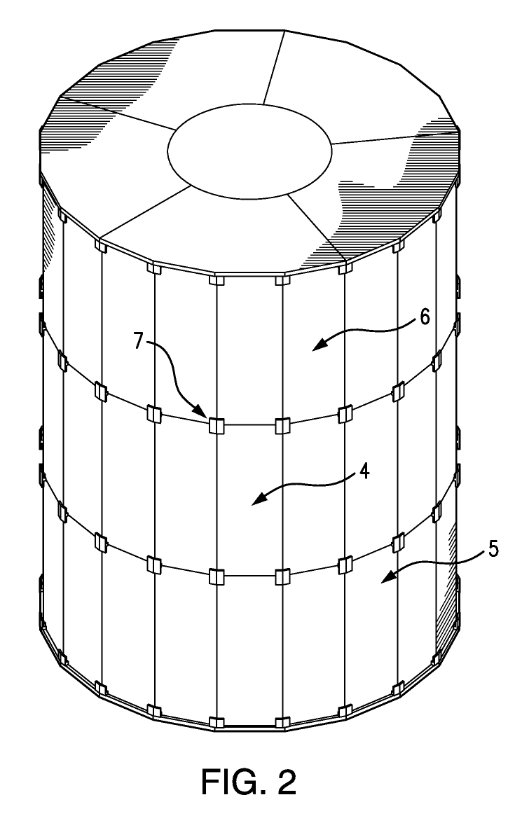

The interlocking of the plurality of insulation panels can be accomplished with the use of one or more connectors that are further described herein in exemplary fashion. For instance, a connector is designed to connect with a corner of each of four insulation panels and other connectors are designed to connect two insulation panels together. This is shown, for instance, in FIGS. 2, 3, and 5.

When at least one insulation layer comprises at least one carbon fiber rigid board or carbon fiber rigidized felt board, the carbon fiber rigid board and/or carbon fiber rigidized felt board can have a carbon fiber to resin weight ratio, for instance, of from 1 part carbon fiber:0.02 part carbonized resin to 1 part carbon fiber:3 parts carbonized resin or other carbon fiber:resin ratios within this range or outside of this range.

The insulation segment, for instance, an insulation panel(s), can have a thickness of from about 10 mm to about 250 mm, from about 15 mm to about 200 mm, from about 20 mm to about 150 mm, from about 50 mm to about 100 mm, or from about 70 mm to about 100 mm, and the like. The panel can have a front flat side and a rear flat side, and, for instance, four edges that define the thickness.

The insulation segment that comprises at least one insulation layer can comprise from one insulation layer to 25 insulation layers or more, wherein each of these insulation layers can be the same or different with respect to materials, properties, thickness, and/or dimensions, and the like. When more than one insulation layer comprises the insulation segment, the total thickness of the insulation segment is as set forth above, namely from about 10 mm to about 250 mm. One insulation layer can have an individual thickness of from about 10 mm to about 250 mm. Generally, when more than one insulation layer is present, the thickness of each individual insulation layer can be more in the range of from about 1 mm to about 100 mm, such as from 10 mm to 70 mm, and the like.

With regard to the various materials that can form at least one insulation layer, the carbon fiber rigid board can be made by mixing carbon fibers with resin or a binder system which can be, for instance, phenolic resin, epoxy resin, novolac resin, or other synthetic resins in the carbon fiber to resin ratio specified earlier. This mixture is then formed into a board, panel shape, or other forms and pressed and heated in order to form the carbon fiber rigid board. The carbon fiber rigid board can be commercially available from Morgan AM&T, and specific commercial examples include Morgan AM&T Rigid Board and Morgan AM&T Solar Grade Rigid Insulation. The carbon fiber rigid board can also be commercially obtained from Mersen, GrafTech International, and others under such trade names as Calcarb CBCF, GRI Insulation system, and others.

Regarding the carbon fiber rigidized felt, this material is formed by impregnating layers of carbon felt with resin or a binder system which can be, for instance, phenolic resin, epoxy resin, novolac resin, or other synthetic resins in the carbon fiber to resin ratio specified earlier. The impregnated felt layers are heated to form the carbon fiber rigidized felt material. The carbon fiber rigidized felt can be commercially obtained from Carbon Composites, Inc., Kureha Corporation, SGL Group, and others under such trade names as CRB-220, KRECA FR, SIGRATHERM® RFA, and others.

The at least one insulation layer can be a rigid-flexible hybrid insulation material, for instance, as described in U.S. Provisional Patent Application No. 61/308,451, filed Feb. 26, 2010, and incorporated in its entirety by reference herein.

The insulation layer can comprise a carbon fiber flexible felt which is a product, for instance, prepared by taking a carbon fiber precursor, such as rayon fiber, and forming this carbon fiber precursor into a bat, and then this batt is needled to lock the fibers together, and then the fibers are heat treated to obtain the carbon fiber flexible felt. Heat treatment temperatures can typically be from 700° C. to 2000° C. Commercially available sources for carbon fiber flexible felt include Morgan AM&T, Kureha Corporation, Nippon Carbon Co., LTD., SGL Group, and others under the trade names VDG, KRECA Felt, CARBOLON®, and SIGRATHERM®, and others.

The insulation layer can be or include a flexible graphite felt which is prepared in a similar way to a carbon fiber flexible felt, but the heat treatment temperature is from 2000° C. to 3000° C. in order to form the flexible graphite felt. Commercially available sources include Morgan AM&T, Kureha Corporation, Nippon Carbon Co., LTD., SGL Group, and others, under the trade names WDF, KRECA Felt, CARBOLON®, and SIGRATHERM®, and others.

The insulation layer can be a carbon foam, for instance, in the form of a rigid body. The carbon foam can be obtained from such sources as Graffech International, Koppers Inc., Touchstone Research Laboratory Ltd., Poco Graphite, Inc., and others, under the trade names GRAFOAM®, KFOAM®, CFOAM®, POCOfoam®, and others.

The insulation layer can be or include a carbon aerogel sheet which is formed by taking carbon aerogel particles and sintering them together in the form of a sheet. Commercially available forms of carbon aerogel sheets include American Aerogel Corporation, and others, under the trade name Aerocore™, and others.

With regard to the insulation segment that comprises at least one insulation layer, the insulation segment can have at least one of the following properties:

a) a thermal conductivity of less than 2.5 W/m/K at 1,600° C. (e.g., less than 2 W/m/K, less than 1.5 W/m/K, less than 1 W/m/K, less than 0.75 W/m/K, 0.1 to 2 W/m/K, 0.3 to 2 W/m/K) when measured in one atmosphere of argon by laser flash method (ASTM E1461);

b) a flexural strength of least 10 psi (10 psi to 100 psi, 15 psi to 100 psi, 20 psi to 100 psi, 25 psi to 100 psi) as measured using four point loading (ASTM C651);

c) a coefficient of thermal expansion of less than 10×10⁻⁶ mm/(mm° C.) (1×10¹⁰ mm/(mm° C.) to 0.9×10⁻⁶ mm/(mm ° C.)) as measured using a dual push-rod dilatometer (ASTM E228); and/or

d) less than 500 ppm (e.g., 5 ppm to 499 ppm, 10 ppm to 400 ppm, 15 ppm to 300 ppm, 20 ppm to 200 ppm) oxygen, and/or less than 20 ppm (e.g., 1 ppm to 19 ppm, 5 ppm to 15 ppm) sodium, and/or less than 20 ppm (e.g., 1 ppm to 19 ppm, 5 ppm to 15 ppm) calcium, and/or less than 20 ppm (e.g., 1 ppm to 19 ppm, 5 ppm to 15 ppm) iron, and/or less than 20 ppm (e.g., 1 ppm to 19 ppm, 5 ppm to 15 ppm) vanadium, and/or less than 20 ppm (e.g., 1 ppm to 19 ppm, 5 ppm to 15 ppm) titanium, and/or less than 20 ppm (e.g., 1 ppm to 19 ppm, 5 ppm to 15 ppm) zirconium, and/or less than 20 ppm (e.g., 1 ppm to 19 ppm, 5 ppm to 15 ppm) tungsten, and/or less than 5 ppm (e.g., 0.1 ppm to 4 ppm, 1 ppm to 3 ppm) boron, and/or less than 5 ppm (e.g., 1 ppm to 19 ppm, 5 ppm to 15 ppm) phosphorus, and/or less than 50 ppm (e.g., 1 ppm to 49 ppm, 1 ppm to 30 ppm, 1 ppm to 20 ppm, 0.1 ppm to 10 ppm) sulfur, or any combinations thereof.

The insulation segment can have property a) alone, property b) alone, property c) alone, or property d) alone. The insulation segment can have property a) and b); a), b), and c); a), b), c), and d); b) and c); b) and d); b), c), and d); c) and d), or any other combination. Preferably, the insulation segment has all of the properties a)-d). With regard to property d), all purity levels can be present, or one or more, two or more, three or more, four or more, five or more, six or more, seven or more, eight or more, nine or more, ten or eleven of them.

When the insulation segment is at least one insulation panel, the panel can have any geometry or shape, such as polygonal, for instance, rectangular. When rectangular, for instance, the dimensions (length and width) can be from about 3 inches (76.2 mm) to about 60 inches (1524 mm), such as from about 10 inches to about 40 inches, and having the thicknesses previously mentioned.

The insulation segment can further comprise one or more secondary materials. The secondary material can be or comprise a vapor barrier paint, graphite foil, carbon fiber composite, vapor barrier coating(s) other than paint, or any combinations thereof. Two or more different types of secondary materials can be present on the insulation segment, either as multiple layers or as a mixture of secondary materials forming one layer. Further, at least one secondary material can be present on one surface of the insulation segment and a different type of secondary material can be on a different surface of the same insulation segment.

As an example, the secondary material can be present on at least one side of at least one insulation layer. For instance, when the insulation segment includes a rectangular panel (for instance, a wall panel or section thereof), or multiple panels, the secondary material can be on the front side and/or back (or rear) side of the rectangular panel and, as an option, the same secondary material or a different secondary material can be on one or more edges of the rectangular panel. As a more specific example, the secondary material can be, for instance, a graphite foil, which can be present on the front side and back side of an insulation layer, such as a panel, and a vapor barrier paint or vapor barrier coating can be on one or more edges of the same insulation layer or panel. As a further example, an insulation layer can have graphite foil present on one or more surfaces of the insulation layer and further can have a vapor barrier coating applied on top of and in contact with the previous applied secondary material.

The secondary material can at least partially encapsulate the insulation segment or a portion thereof. The secondary material can fully encapsulate the insulation segment or a portion thereof or a layer thereof.

The vapor barrier coating of the secondary material can comprise glassy carbon, pyrolytic carbon, pyrolytic graphite, carbon, graphite, diamond, silicon carbide, tungsten carbide, tungsten carbide, tantalum carbide, or any combination or mixture thereof. The vapor barrier coating may be prepared by chemical vapor deposition of the coating to the surface of the material. The vapor barrier coating can also be prepared by mixing glassy carbon, pyrolytic carbon, pyrolytic graphite, carbon, graphite, diamond, silicon carbide, tungsten carbide, tungsten carbide, and/or tantalum carbide, or any combinations thereof in a carrier, such as at least one resin, and the coating can be applied as a wet coating onto the insulation segment or a layer thereof using any coating technique, such as spraying, rolling, brushing, and the like. Commercial examples of these vapor barrier coatings include CVD pyrolytic carbon, CVD diamond coating, and others, under the trade name Pyrocarbon (Tornier), UNCD (Advanced Diamond Technologies, Inc.), and others. The vapor barrier coating can have a dry thickness on the insulation segment or layer thereof of from 0.005 mm to about 5 mm or other thicknesses, and be applied and present in one or more coating layers. The coating layers, if more than one are used, can be the same or different from each other.

The vapor barrier paint, for instance, can be graphite paint and/or carbon paint and can be applied in the same manner as the vapor barrier coatings. The vapor barrier paint can have a thickness on the insulation segment or layer thereof of from 0.05 mm to 5 mm or other thicknesses. The vapor barrier paint can be applied such that one or more than one layer is present, wherein each layer can be the same or different from each other. Commercial examples of vapor barrier paint include graphite paint coating, under the trade name BC-501 (Bay Composites, Inc.), Acheson DAG137 (Henkel Corporation), and others.

With regard to the graphite foil, the graphite foil, for instance, can have a thickness of from about 0.15 mm to about 15 mm, or from about 0.5 mm to about 1 mm, from about 0.5 mm to about 5 mm, or from about 0.75 mm to about 1 mm. The graphite foil can be natural graphite that is expanded and heat treated and rolled into sheets and then heat treated again to obtain a flexible material. Commercial sources for the graphite foil include GrafTech International, SGL Group, and others under the trade name GRAFOIL®, SIGRAFLEX®, and others.

With regard to the carbon fiber composite, the carbon fiber composite can have a thickness, for instance, of from about 0.1 mm to about 50 mm, from about 1 mm to about 25 mm, from about 5 mm to about 20 mm, and the like. The carbon fiber composite, also known as CFC, can be made from woven layers of carbon fiber formed into cloth and then impregnated with resin, such as the resins identified above, and then heat treated. Commercial sources for the CFC include Carbon Composites, Inc., Bay Composites, Inc., and others, under the trade name CCP, BC-1000, and others.

The insulation segment can shield or insulate or protect the reactor or furnace or part thereof from any heat and/or chemicals (such as chemical gases). For instance, the insulation segment can shield, insulate, and/or protect any material on the opposite side of the insulation segment, such as the outer metal casing of the reactor or furnace.

With respect to the shield segment, the shield segment can comprise at least one shield layer. The shield layer or layers can comprise a graphite plate, a carbon fiber composite, a carbon fiber rigid board, a carbon fiber rigidized felt, a rigid-flexible hybrid board, or any combination thereof. For example, the shield segment can comprise multiple shield layers that can be the same or different from each other with respect to the material, thickness, structural properties, and/or physical properties, and the like. For example, the shield segment can comprise two or more shield layers, and one of the shield layers can be a graphite plate and another shield layer that forms the same shield segment can be a carbon fiber composite. Any combination of different shield layers can be used to form the shield segment. When more than one shield layer is used to form the shield segment, the two or more shield layers can be bonded or otherwise permanently or removably affixed together to form a composite. For instance, two or more shield layers can be laminated together using various techniques, such as applying heat and pressure to the insulation layers, such as a temperature of 100 degrees C. to 1,000 degrees C. The shield segment (e.g., wall(s)) that comprises at least one shield layer can take the form of or comprise a plurality of shield panels, such as wall panels. These shield panels can have identical dimensions with respect to each other and be part of the same containment system, or, as an option, the shield panels can have different dimensions. Furthermore, the shield panels can have the same or different dimensions from the insulation panels described herein. The shield panels, as an option, can have the same materials that comprise each shield panel, or, as an option, one or more shield panels can contain a different shield layer or layers from other one or more shield panels.

The shield segment, when comprising a plurality of shield panels, can have a panel design or structure that permits the interlocking of the shield panels together, such as shown in some of the figures herein, for instance, an interlocking feature(s) (e.g., tongue and groove, protruding lip, and the like to achieve a mechanical locking), and/or the use of connectors. The shield segment can include or take the shape of a wall and the plurality of shield panels can be wall panels (or sections thereof) that form the wall. The wall can encircle a reactor of furnace or part thereof. The shield segment can shield the reactor or furnace or part thereof from any chemicals (such as chemical gases). For instance, the shield segment can shield or protect any material on the opposite side of the shield segment, such as the insulation segment, if present, and/or the outer metal casing of the reactor or furnace.

The interlocking of the plurality of shield panels can be accomplished with the use of an interlocking feature on the panels (e.g., tongue and groove) and/or with the use of one or more connectors that are further described herein in exemplary fashion. For instance, a connector is designed to connect with a corner of each of the four shield panels and other connectors are designed to connect two shield panels together. This is shown, for instance, in FIGS. 2, 3, and 5. Further, as an option, the same connectors can be used to connect insulation panels together and shield panels together as shown in the figures. Essentially, in this option, the insulation panels and shield panels are adjacent to each other and both fit within the same groove or slot of the connector.

The shield segment, for instance, a shield panel(s), can have a thickness of from about 3 mm to about 70 mm, from about 5 mm to about 60 mm, from about 10 mm to about 50 mm, and the like.

The shield segment that comprises at least one shield layer can comprise from one shield layer to 25 shield layers or more, wherein each of these shield layers can be the same or different with respect to materials, properties, thickness, and/or dimensions, and the like. When more than one shield layer comprises the shield segment, the total thickness of the overall shield segment is as set forth above, namely from about 3 mm to about 70 mm. One shield layer can have an integral thickness of from about 3 mm to about 70 mm. Generally, when more than one shield layer is present, the thickness of each individual shield layer can be more in the range of from about 1 mm to about 20 mm, such as from about 3 mm to about 10 mm, and the like.

With regard to at least one shield layer that can comprise a carbon fiber rigid board, carbon fiber rigidized felt board, and similar materials which contain carbon fiber, the carbon fiber to resin weight ratio can be, for instance, of from 1 part carbon fiber:0.02 part carbonized resin to 1 part carbon part:3 parts carbonized resin, or other carbon fiber:resin ratios within this range or outside this range.

With regard to the various materials that can form at least one shield layer, the graphite plate can be obtained commercially from Morgan AM&T under product name EY308. The graphite can be cut/machined into the proper shape of a shield panel(s).

The graphite plate in the shield segment can be extruded graphite, uniaxially pressed graphite, isostatically pressed graphite, and the like.

The graphite plate can have at least one or more of the following properties:

a) an apparent density of at least 1.7 g/cm³ (e.g., 1.7 g/cm³ to 2.5 g/cm³, from 1.8 g/cm³ to 2.5 g/cm³, from 2.0 g/cm³ to 2.5 g/cm³);

b) a flexural strength of at least 8,500 psi (e.g., from 8,500 psi to 15,000 psi, from 10,000 psi to 15,000 psi, from 12,000 psi to 20,000 psi) as measured using four point loading (ASTM C651);

c) a compressive strength of at least 13,500 psi (e.g., from 13,500 psi to 20,000 psi, from 15,000 psi to 20,000 psi, from 17,500 psi to 25,000 psi) (ASTM C695);

d) a co-efficient of thermal expansion of less than 5×10⁻⁶ mm/(mm ° C.) (e.g., 0.1×10⁻⁶ to 4.9×10⁻⁶ mm/(mm ° C.) or from 1×10⁻⁶ mm/(mm ° C.) to 1×10⁻⁷ mm/(mm ° C.) as measured using a dual push-rod dilotometer (ASTM E228);

e) a Shore hardness of at least 50 (e.g., 50 to 100, 60 to 100, 70 to 100);

f) a porosity of 15% or less (e.g., 1% to 15%, 5% to 15%, 2% to 10%); and/or

g) a purity of less than 20 ppm (e.g., 1 ppm to 19 ppm, 5 ppm to 15 ppm) sodium, less than 20 ppm (e.g., 1 ppm to 19 ppm, 5 ppm to 15 ppm) calcium, less than 20 ppm (e.g., 1 ppm to 19 ppm, 5 ppm to 15 ppm) iron, less than 20 ppm (e.g., 1 ppm to 19 ppm, 5 ppm to 15 ppm) vanadium, less than 20 ppm (e.g., 1 ppm to 19 ppm, 5 ppm to 15 ppm) titanium, less than 20 ppm (e.g., 1 ppm to 19 ppm, 5 ppm to 15 ppm) zirconium, less than 20 ppm (e.g., 1 ppm to 19 ppm, 5 ppm to 15 ppm) tungsten, less than 5 ppm (e.g., 0.1 ppm to 4 ppm, 1 ppm to 3 ppm) boron, less than 5 ppm (e.g., 0.1 ppm to 4 ppm, 1 ppm to 3 ppm) phosphorus, or less than 50 ppm (e.g., 1 ppm to 49 ppm, 1 ppm to 30 ppm, 1 ppm to 20 ppm, 0.1 ppm to 10 ppm) sulfur, or any combination thereof. All purity levels here and throughout are by weight.

The graphite plate(s) can have property a) alone, property b) alone, property c) alone, property d) alone, property e) alone, property f) alone, or property g) alone. The shield segment can have any combination of properties, such as a) and b); a), b), and c); a), b), c), and d); a), b), c), d), and e); a)-f); a)-g), or any combinations of these various properties. Preferably, the shield segment has all of the properties a)-g). With regard to property g), all purity levels for the listed elements can be present or one or more, two or more, three or more, four or more, five or more, six or more, seven or more, eight or more, or nine or more, can be present in any combinations.

The shield segment, for instance, a shield panel(s), can have a thickness of from about 3 mm to about 70 mm, from about 5 mm to about 50 mm, from about 10 mm to about 40 mm, from about 15 mm to about 40 mm, and the like. The shield segment as a panel(s), can have a front flat side and a flat rear side, and for instance, four edges that define the thickness. When the shield segment is at least one shield panel, the panel can have any geometry or shape, such as polygonal, for instance, rectangular. When rectangular, for instance, the dimensions (length and width) can be from about 3 inches (76.2 mm) to about 60 inches (1524 mm), such as from about 10 inches to about 40 inches, and having the thicknesses previously mentioned.

The shield layer can comprise a carbon fiber composite, also known as a CFC, as described earlier. The at least one shield layer can comprise a carbon fiber rigid board as described above with respect to the insulation layer. The at least one shield layer can comprise a carbon fiber rigidized felt as described above. The at least one shield layer can comprise a rigid-flexible hybrid as described above for the insulation material.

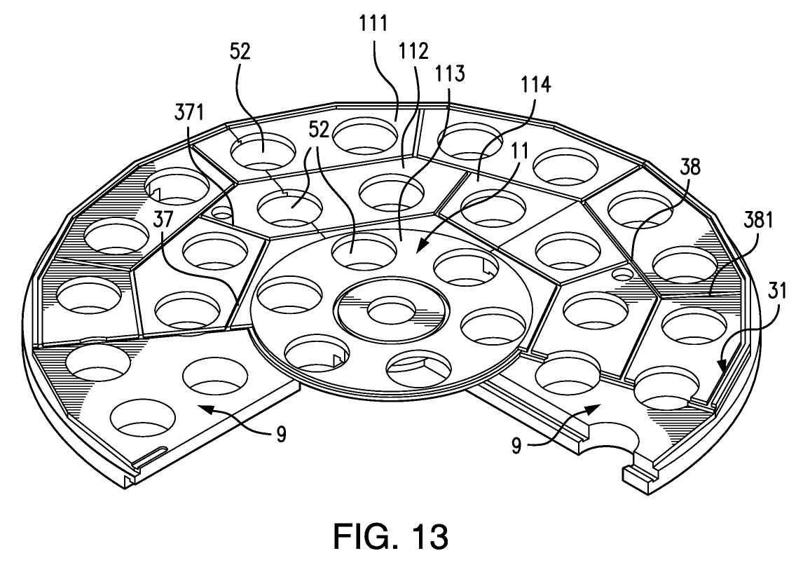

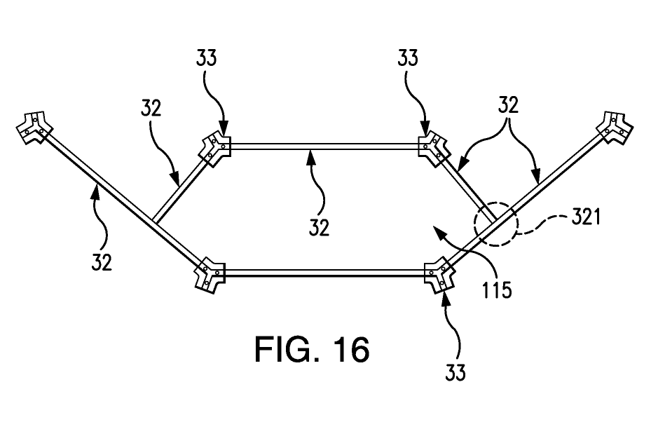

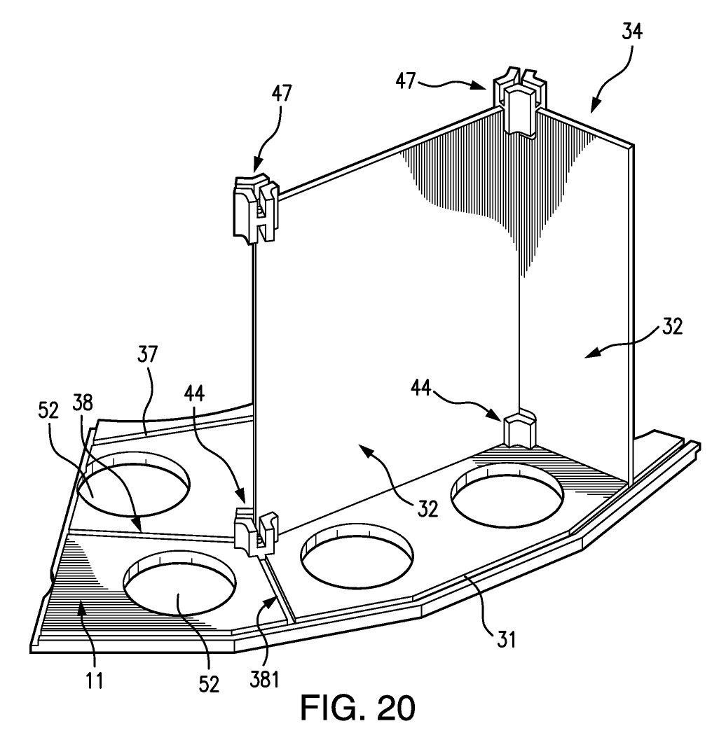

With regard to the divider segment, as shown in the figures, the divider segment can divide various sections of a reactor or furnace from other sections of the same reactor or furnace. The divider segment can comprise one or more panels or sections thereof, to form a wall or a series of interconnecting walls within the reactor or furnace. The divider segment can be encircled or surrounded by the insulation segment and/or shield segment. For instance, a divider segment can separate or isolate various internal heater rods or filaments or sections thereof from each other. As shown, for instance, in FIG. 13, the reactor base plate has a series of openings, such as cylindrical holes, that receive the heater rods or filaments, and these various holes that receive the filaments can be sectioned off from each other using divider plates that form sectional walls. The sectioning off of the various holes or grouping of holes that receive the heating rods, for instance, is shown in FIG. 20 and FIG. 16. The divider segment can comprise at least one divider layer. The divider layer or layers can comprise the same materials as at least one shield layer, for instance, a graphite plate, and/or a carbon fiber composite, and/or a carbon fiber rigid board, and/or a carbon fiber rigidized felt, and/or a rigid-flexible hybrid board, or a combination thereof. The divider plate can have the same dimensions, parameters, and/or properties as the at least one shield layer mentioned above and those are incorporated herein by reference. Any combination of different shield layers can be used to form the divider segment. When more than one divider layer is used to form the divider segment, the two or more divider layers can be bonded or otherwise permanently or removably affixed together to form a composite. For instance, two or more divider layers can be laminated together using various techniques, such as applying heat and pressure to the insulation layers, such as a temperature of 100° C. to 1,000° C.

The divider segment that comprises at least one divider layer can take the form of or comprise a plurality of divider panels. The divider panels can form a wall or sections thereof, such as a series of interconnecting walls, that can intersect each other. These divider panels can have identical dimensions with respect to each other and can be part of the same containment system or, as an option, the divider panels can have different dimensions. Further, the divider panels can have the same or different dimensions and sizes from the insulation panels and/or shield panels. The divider panels, as an option, can have the same materials that comprise each divider panel, or, as an option, one or more divider panels can contain a different divider layer or layers from other one or more divider panels. The divider segment divides the various parts of the reactor or furnace from other parts of the same reactor or furnace. The divider segment can further serve as a shield in the same manner as the shield segment.

The divider segment, when comprising a plurality of divider panels, can have a panel design or structure that permits the interlocking of the divider panels together, such as shown in the figures herein. This can be accomplished by the divider panels having interlocking features (e.g., tongue and groove) and/or through the use of connectors. The interlocking of panels can be vertical and/or laterally, so as to form a wall or a series of walls.

The divider segment, for instance, a divider panel(s), can have a thickness of from about 3 mm to about 70 mm, from about 5 mm to about 50 mm, from about 10 mm to about 40 mm, from about 15 mm to about 40 mm, and the like. The divider segment as a panel(s), can have a front flat side and a flat rear side, and for instance, four edges that define the thickness. When the divider segment is at least one divider panel, the panel can have any geometry or shape, such as polygonal, for instance, rectangular. When rectangular, for instance, the dimensions (length and width) can be from about 3 inches (76.2 mm) to about 60 inches (1524 mm), such as from about 10 inches to about 40 inches, and having the thicknesses previously mentioned.

The interlocking of the plurality of divider panels can be accomplished with the use of one or more connectors that are further described herein in an exemplary fashion. The divider segment, for instance, a divider panel(s) can have the same total thickness and/or thicknesses for individual divider layers as the shield segment.

In any of the layers present in the insulation segment and/or the shield segment and/or the divider segment, fillers, such as carbon black particles, coke particles, and/or ceramic fibers may be present. Any of the layers of the insulation segment and/or the shield segment and/or the divider segment can comprise carbon fibers, such as with a Denier or linear mass density ranging from approximately 1.0 to 50 Denier. The insulation segment and/or the shield segment and/or the divider segment or any layer(s) thereof may have a density ranging from approximately 0.05 to 0.15 g/cc.

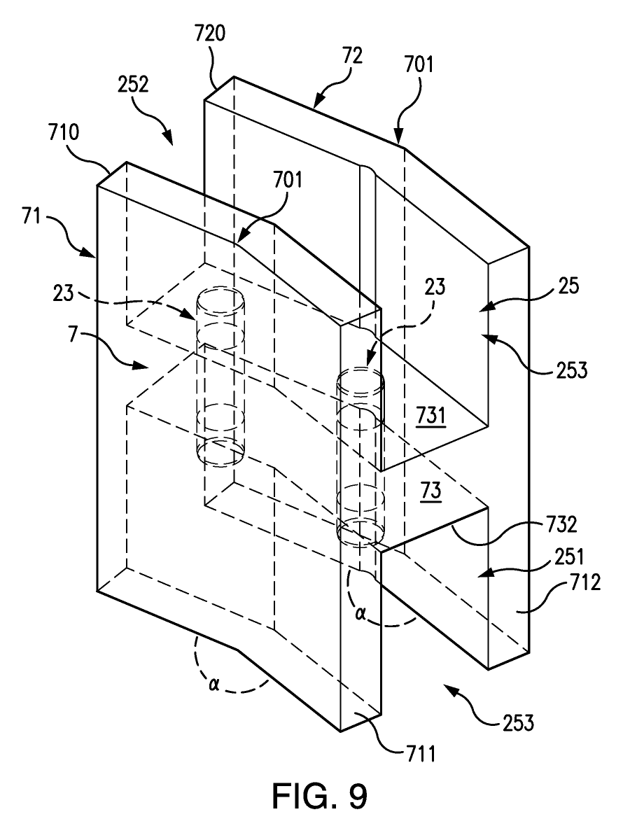

The insulation segment and/or shield segment can have a top lid and a base made of the same material as each respective segment and the top lid and/or bottom base can be one piece or several pieces that join together and optionally can be interlocking if desired. The base can have the same design template as the base plate of the reactor or furnace, such as with a multiplicity of holes to receive heater rods as, for instance, shown in FIG. 13. When several pieces are used to form the base plate, the various pieces can have an interlocking design as shown, for instance, in FIG. 9, where a ledge can be present for each panel forming the base, so that the pieces connect together.

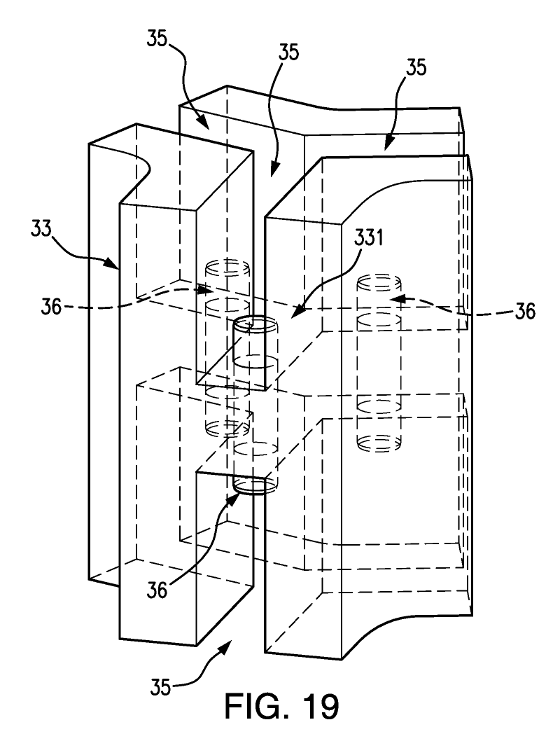

The connector can be of the various shapes, for instance, as set forth in the figures (for instance, FIG. 19 or FIGS. 21-28). These various connectors can be used to connect the plurality of insulation panels that form the insulation segment and/or can be used to connect a plurality of shield panels that form the shield segment, and/or can be used to connect the various divider panels that form the divider segment. These connectors can be made from or comprise graphite, and the connector can be machined to the various shapes shown in the figures, for instance. The graphite of the connectors can have the same properties as the graphite described above for the shield panel in order to ensure that the connector will resist the conditions of the reactor or furnace.

For purposes of the present invention, the secondary material referenced earlier for the insulation segment can optionally be present with the shield segment and/or divider segment and/or one or more connectors. The details and options regarding the secondary material apply equally here and are incorporated by reference herein to avoid repeating it. The secondary material can partially or fully encapsulate any component(s) of the containment system in the manner described earlier with respect to the insulation segment.

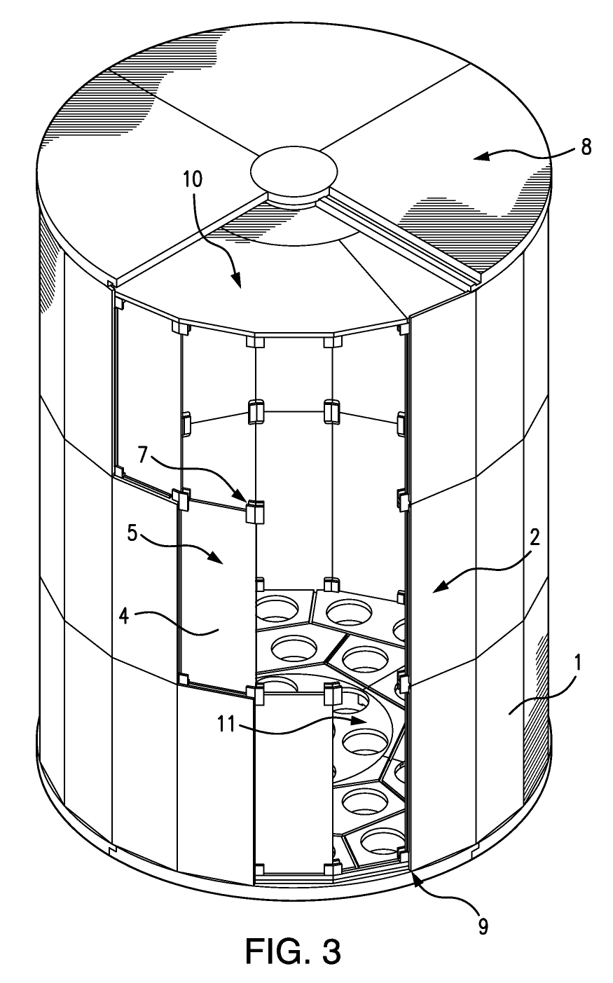

As stated above, the insulation segment can encircle the shield segment, for instance, as shown in FIG. 3. The insulation segment can be in physical contact with the shield segment. The insulation segment can be cylindrical or polygonal. The shield segment can be cylindrical or polygonal, for instance, as shown in FIG. 3.

The insulation segment and shield segment can be a wall or walls that encircle a heater of a reactor or heater rods of a reactor and the like. The insulation segment and shield segment can be adjacent to each other (and/or parallel to each other) such that a gap of no greater than 15 cm exists between the insulation segment and the shield segment. The insulation segment and the shield segment can touch each other or form a gap that is 10 cm or less, 5 cm or less, 1 cm or less, or 0.5 cm or less. When the gap is extremely small or non-existent, it avoids any spaces that would hold gases, such as methane, which can be dangerous if the build-up is large in a reactor.

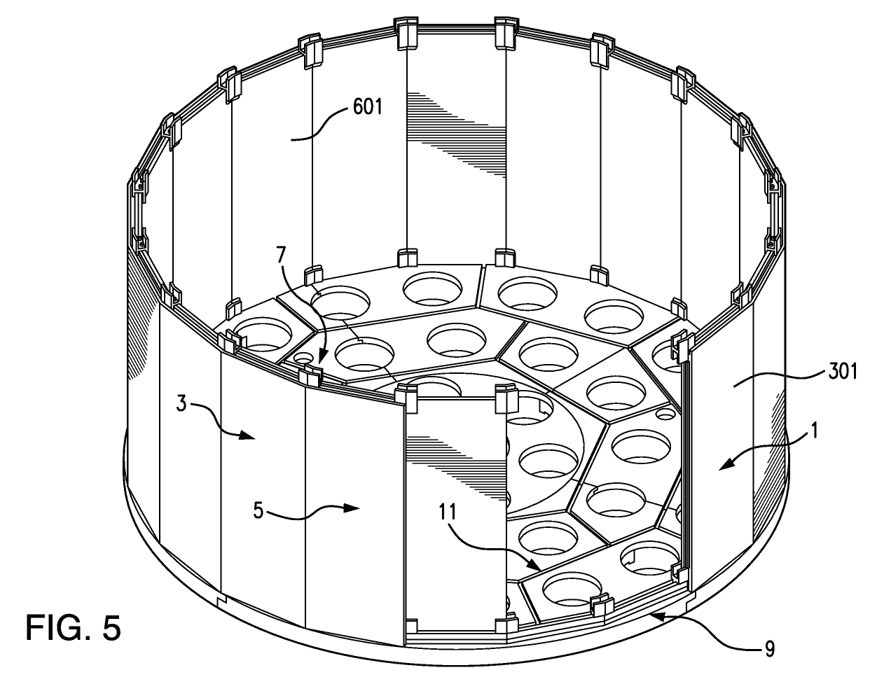

The insulation segment can comprise, as stated, a plurality of insulation panels that are interlocked together to form a cylindrical or polygonal shape, and the shield segment can comprise a plurality of shield panels that are interlocked together to form a cylindrical or polygonal shape. The insulation panels can be interlocked together by a plurality of connectors, and these same (or different ones) connectors can also interlock a plurality of the shield panels together, such as shown in FIGS. 5, 6, and 7.

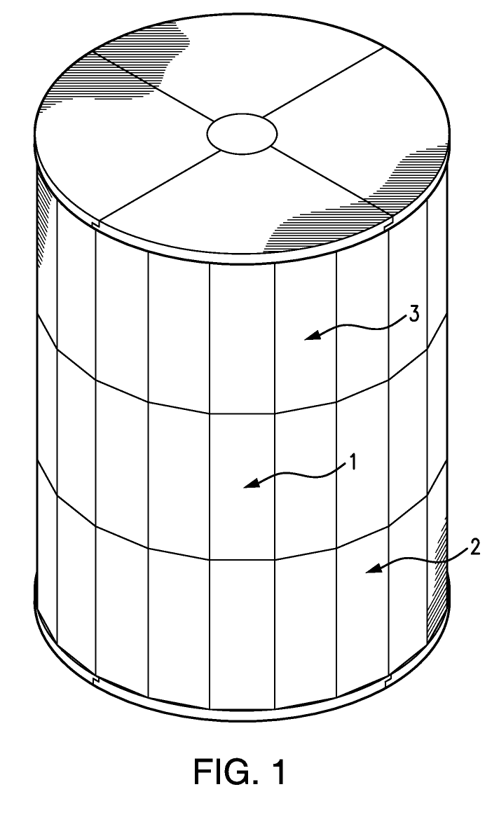

Referring to FIGS. 1-31, as a non-limiting illustration, various features of an outer insulation segment 1, shield segment 4, and divider segment of the containment system of the present invention are shown. Unless indicated otherwise, similarly-used identifying numbers in these figures refer to the same features.

Referring to FIG. 1, an outer insulation segment 1 is formed from an assembly of a plurality of insulation panels 2 joined together by suitable interlocking mechanisms, which are illustrated in greater detail in other figures herein. The outer insulation segment 1 can be built up from ring shaped sub-assemblies 3 assembled from individual interlocking insulation panels 2. The size and number of vertically-stacked ring shaped sub-assemblies 3 determines the height of the outer insulation segment 1. Ring-shaped sub-assemblies 3 can be stacked, for example, three high such as shown in FIG. 1, or other numbers (e.g., 2, 4, 5, 6, and so forth).

Referring to FIGS. 2 and 3, an inner shield segment 4 is sized to fit within outer insulation segment 1. Inner shield segment 4 is formed from an assembly of a plurality of shield panels 5. The inner shield segment 4 can be built up from ring shaped sub-assemblies 6 assembled from individual interlocking shield panels 5 in cooperation with connectors 7. The size and number of ring shaped sub-assemblies 6 determines the height of the inner shield segment 4. Ring-shaped sub-assemblies 6 can be stacked, for example, three high such as shown in FIG. 1, or other numbers (e.g., 2, 4, 5, 6, and so forth). Referring further to FIG. 3, a lid (top) 8 and a base plate (bottom) 9 of the outer insulation segment 1, and a lid (top) 10 and base plate (bottom) 11 of the inner shield segment 4, also are shown in a partial fragmentary view.

There is no restriction to the extent to which either the outer insulation segment or inner shield segment is broken down into individual panels. The simplest but very effective panel for use in the present invention is of a rectangular or square shape or other polygonal shape. As shown in various figures herein, each panel of the outer insulation segment and the inner shield segment is rectangular in shape. The insulation segment can be assembled, for example, from three rings, each ring formed from twenty interlocked panels, or other numbers. Thus, a total of sixty panels, for example can make up the cylindrical body of the outer insulation segment. The inner shield segment also can be assembled, for example, from three rings, each formed from twenty interlocked panels or other numbers. As indicated, the interlocked shield panels are joined at the top and bottom of each panel by connectors that can bridge between ring sub-assemblies thereof. For the purpose of providing protection in a thermal convertor, the height and width of each panel 5 in the inner shield 4 may, for example, be 27.2 inches (69.0 cm) and 9.6 inches (24.2 cm) respectively, or other dimensions. For the purpose of providing thermal insulation in a thermal convertor, the height and width of each panel 2 in the outer insulation segment 1 may be, for example, 27.9 inches (70.8 cm) and 9.99 inches (25.4 cm), respectively, or other dimensions. Although the insulation segment and shield segment are shown assembled as a cylindrical body in FIG. 3, for example, the present invention is not restricted to a cylindrical shaped body, and any other shaped body that provides effective insulation around the conversion chamber, e.g., a tubular body of elliptical, angular, or any required cross section, may be used.

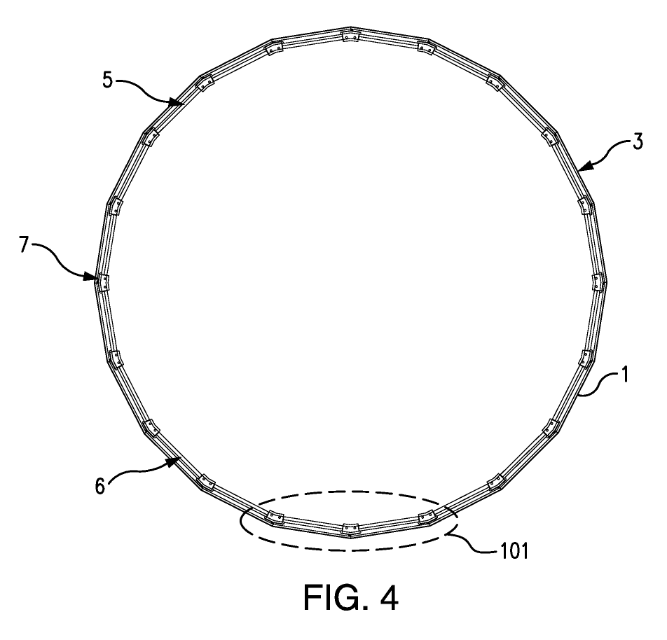

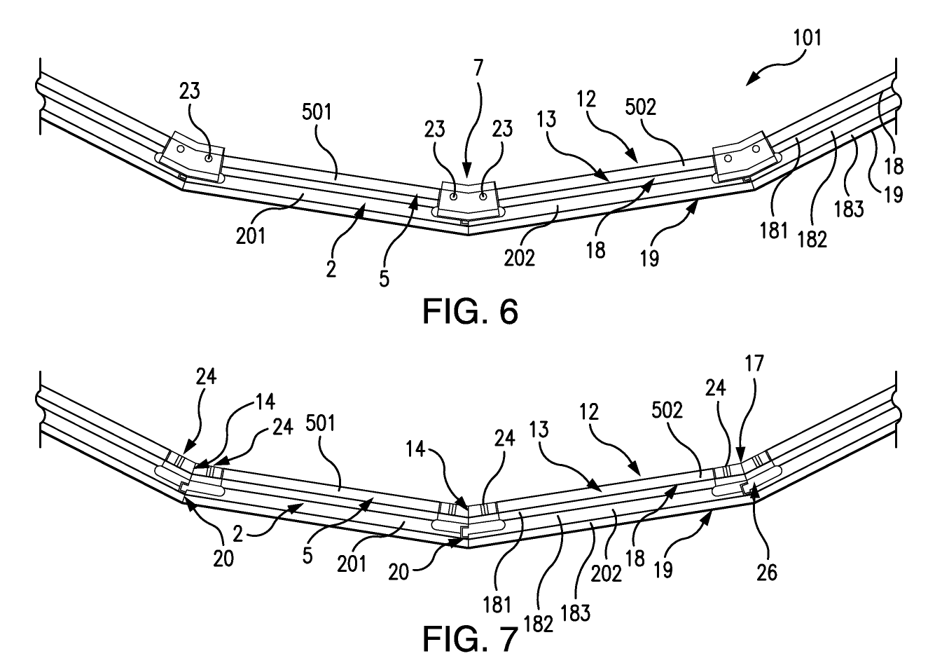

Referring to FIG. 4, an assembly of the outer insulation segment 1 and inner shield segment 4 is shown in cross section with ring shaped sub-assembly 6 of the inner shield segment 4 arranged concentrically inside and adjacent ring shaped sub-assembly 3 of the outer insulation segment 1. Portion 101 indicated in FIG. 4 is discussed in greater detail in FIGS. 6 and 7.

Referring to FIG. 5, assembly of a lowest ring sub-assembly 301 of the outer insulation segment 1 on base plate 9 and a lowest ring sub-assembly 601 of the inner shield segment 4 on the base plate 11 are shown in a partial fragmentary view. Middle connectors 7 are used to connect top corners of the inner shield panels 5 to other inner shield panels stacked thereon, such as shown in other figures (e.g., FIGS. 2-3).

Referring to FIGS. 6 and 7, portion 101 of the assembly shown in FIG. 4 is shown in an enlarged view. Inner shield panels 501 and 502 are connected with middle connector unit 7, which include connector pins 23. Other shield panels 5 are similarly joined with a similar connector unit. As shown with respect to shield panel 502, and applicable to other shield panels, the panel has an inner wall 12 and an outer wall 13. Outer insulation panels 201 and 202 abut each other at side walls 20. As shown with respect to insulation panel 202, and applicable to other insulation panels, the panel has an inner wall 18 and an outer wall 19. The insulation panels 2 (e.g., 201, 202) can be a single unitary part having profiled side edges, such as indicated herein. The segments 181, 182, and 183 shown between walls 18 and 19 indicate changes in elevation at these edges of the insulation panels 2. For example, raised ridge segment 182 can have lower ledge segments 181 and 183 on each adjacent side thereof. In FIG. 7, connectors 7 are removed to show some features of the junctions between the insulation panels 2 and shield panels 5. Slots 24 on inner shield panels 5 can receive pins 23 of the connector 7, when interfitted in alignment therewith.

It is preferable in the outer insulation segment that the interlocking feature at the joints between successive units defines a tortuous path along side walls 20 between the interior and exterior face of the insulation liner segment to inhibit heat loss and the containment of the exhaust gases. The insulation panels 2 can be snap-fitted together to provide a secure joint and to prevent them from disassembling. For the inner shield panels 5, it is not necessary for a tortuous path to be defined between the interior and exterior face of the insulation liner. Tight fitting butt joints 17, in combination with connectors 7, can be sufficient to contain the reaction gas to the interior of the chamber. Each side wall of the panel 5 may be angled in such a way that when adjacent panels butt against each other, they can be assembled into a ring.

Preferably, the front (inner) 12 and rear (outer) 13 walls of each shield panel 5 of the inner shield segment, and the front (inner) 18 and rear (outer) 19 walls of each insulation panel 2 of the outer insulation segment can be flat and parallel. In comparison to curved or arcuate type faces, flat faces can be easier to form requiring limited machining operations. Examples of forming techniques include but not limited to pressing, such as isostatic pressing and iso-pressing or casting. The recess and projections forming the interlocking features can be machined into the unit or formed during the forming operation. If the front and rear facing walls are flat, the ring can have a polygonal configuration. To more closely approximate a cylindrical form, it can be preferred that the rings are formed from 10 or more, preferably 20 more panels. FIGS. 1 to 3, in these illustrations, show a perspective view of the outer insulation segment 1 and inner shield segment 4 fabricated from an assembly of a plurality of interlocked panels 2 and 5, wherein the front (inner) 12 and 18 and rear (outer) walls 13 and 19 of each panel 2 and 5 are flat and parallel, the cross-section of which having a polygonal configuration.

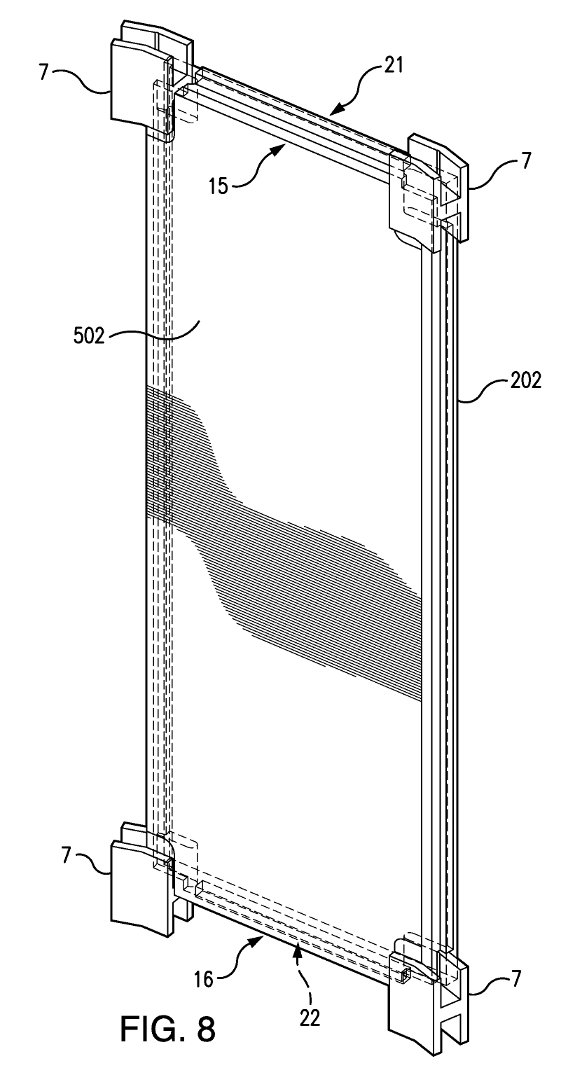

Referring to FIG. 8, insulation panel 202 having a top 21 and bottom 22 is shown in assembly with inner shield panel 502 having a top 15 and bottom 16, with connectors 7 shown in their installed positions at the corners of the assembly.

Referring to FIG. 9, a middle connector 7 is shown having a pair of spaced apart, parallel extending upright wall members 71 and 72 which are joined by a laterally-extending bridge member 73 having upper-facing bottom wall 731 and a lower-facing bottom wall 732. The bridge member 73 defines the lateral spacing between members 71 and 72. Upper and lower slots 25 and 251, respectively, are defined between the wall members 71 and 72 and the upper- and lower-facing bottom walls 731 and 732 of bridge member 73. The bridge member 73 is located approximately at the mid-height of wall members 71 and 72. A cross-section of connector 7 generally can be an H-shape. Middle connector 7 has a corner or bend 701 in the medial area of each of pair of upright wall members 71 and 72, and bridge member 73. This bend 701 connects spaced apart, parallel extending wall member portions 710, 720 and 711, 712, which extend above and below bridge member 73. Each slot 25, 251 can be formed of two intersecting channels 252, 253. Channels 252 and 253 can form a squared U-shape or U-shape. The bend 701 can define an angle α (alpha) between the two intersecting channels 252, 253. The angle defined between the two channels 252, 253 can be, for example, about 160° to about 164° (e.g., about) 162°. The connector 7 usually is arranged on an inner shield segment (5) wherein the angle α (and bend 701) of the connector faces in the same direction as the inner wall (12) of the inner shield segment panel 5 such as shown in FIGS. 6-7. Pins 23 project into channels 252, 253 of the slots 25, 251 above and below bridge member 23. The projection distance into the respective channels can be, for example, the same for each pin 23. The pins 23 of the connector 7 can be part of the same body of the entire connector 7. Pins 23 can be made, for example, as machined features from the same, single piece used to form the rest of the connector body, such as, for example, graphite.

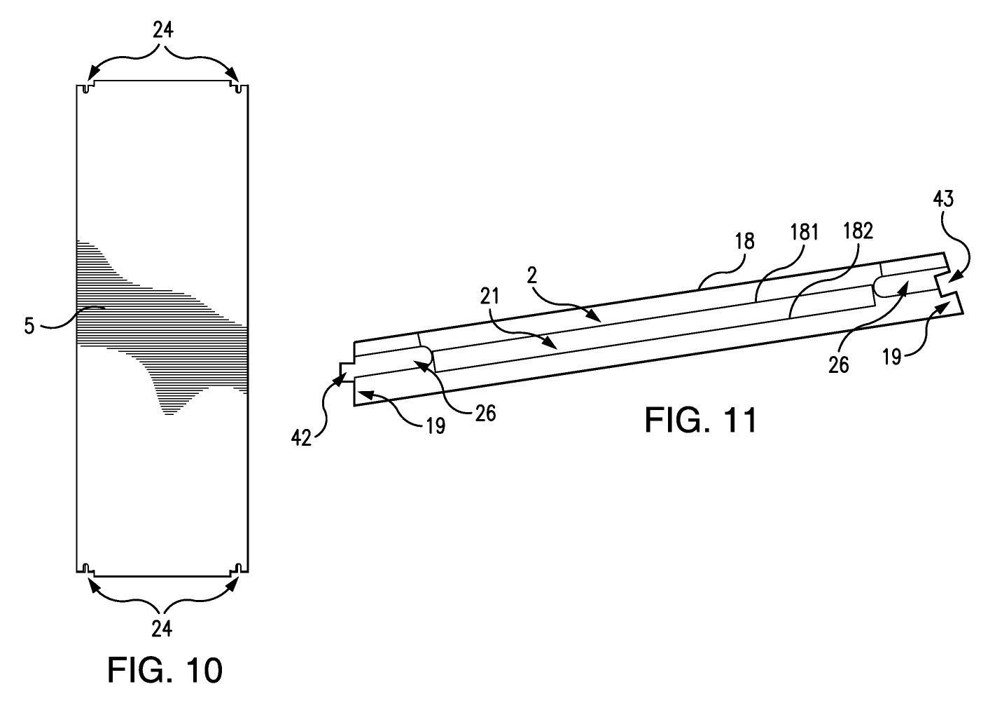

Referring to FIG. 10, a single inner shield panel 5 is shown with slots 24 at the four corners of the panel which are adapted for receiving pins 23 of the connectors, such as middle connectors 7 or top or bottom connectors shown in other figures herein.

Referring to FIG. 11, the top 21 of an insulation panel 2 is shown having a tongue portion 42 on one lateral side and a groove portion 43 on the opposite lateral side of the panel 2. Each side wall 20 of the outer insulation segment panels comprises a slot 26 extending along the panel which co-operates with a complementary slot on an adjacent panel to form a channel to interlock the adjacent units together using a connector, such as the middle connector 7. As indicated, FIGS. 6 and 7 show an example of a joint made between two abutting successive panels 2 having a tongue 42 and groove 43, which also are shown in FIG. 11. The slots 26 of adjacent panels can be aligned for interlocking of the tongue and groove in order to lock the panels 2 together (see FIGS. 6-7). Not only does this type of interlocking mechanism lock adjacent panels in a ring, but offers a tortuous path between the interior and exterior face of the insulation liner for inhibiting heat loss. In addition to the tongue and groove arrangement, the use of a channel and key or dovetail mechanism which snap-fit together are alternative mechanisms to create such interlocking. The connectors 7 may not only join the inner shield panels, but may also interlock the inner shield panels to the outer insulation segment. In the present example, the design of connector 7 can provide a slot 25 (or 251) that gathers in the inner shield panel 5 and adjacent outer insulation panel 2 by capturing the panel 2 in slot 26. Slots 26 on opposite sides of panels 2 indicated in FIG. 11 are configured, for example, to receive wall portions 712, 720 of middle connector 7, such as shown in FIG. 9, when the connector is jointly interconnected with an inner shield panel 5, such as shown in FIGS. 6-7.

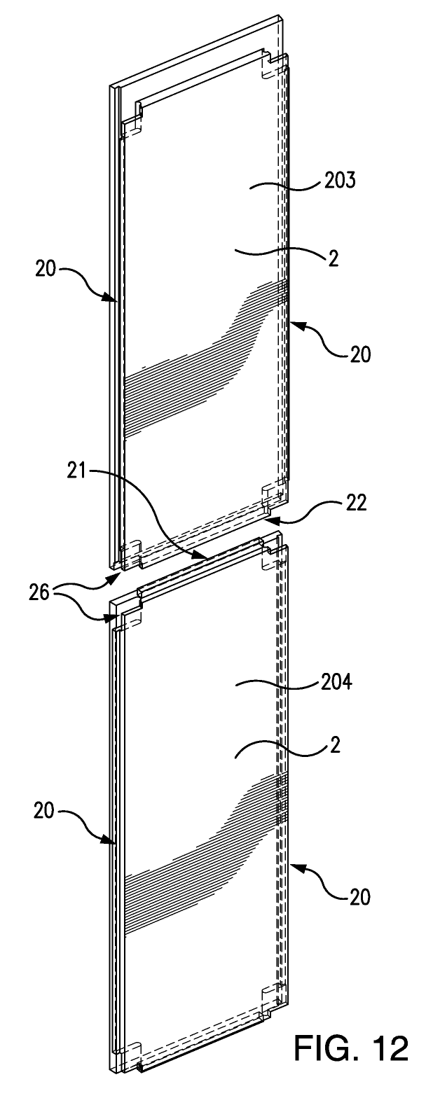

Referring to FIG. 12, two insulation panels 2, which are labeled as panels 203 and 204, have sidewalls 20 and slots 26 are shown in vertical spaced apart orientation before assembly. In addition to the interlocking features formed at the side walls of the outer insulation panels such as shown with respect to FIGS. 6, 7, and 11, the top 21 and bottom 22 of each insulation panel 203 and 204 can also be formed with an interlocking mechanism. In the particular embodiment as shown in FIG. 12, the top 21 and bottom 22 of each panel comprises a tongue 21 and groove 22 arrangement and respectively co-operate with a recess and projection from neighbouring panels above and below the panel. By having interlocking features on all four sides of each panel 2 as shown in FIG. 12, it not only allows either side of the each unit to cooperate with neighbouring panels laterally disposed at either side of the panel, but also the top and bottom of the panel can also co-operate with neighbouring panels disposed above and below the panel. In use, each panel can be interlocked within a ring of the insulation segment and the height of the insulation segment can be increased by successively increasing the number of rings to form a cylindrical body as shown in FIGS. 1-3.

Referring to FIG. 13, the inner shield segment base plate 11 including an outer ring-shaped groove 31, and an underlying outer insulation segment base plate 9, are shown in partial fragmentary view. Groove 31 can receive a terminating connector and panels of the inner shield such as illustrated herein. Interior ring-patterned slots 38 and 37, and radially extending slots 381 and 371, which connect groove 31 and ring-patterned slot 38, or slots 38 and 37, respectively, can sub-divide the surface of base plate 11 into multiple regions 111, 112, 113, 114, and so forth. These divider plate-receiving grooves and/or slots can completely surround one more holes 52. Holes 52 extend completely through base plates 9 and 11. Holes 52 can be used, for example, for accommodating heater rods of the converter. The subdivided regions 111, 112, 113, and 114, can be surrounded with divider plates, such as shown in illustrations herein, to provide channels. As illustrated, the sub-divided regions can have similar or different geometries.

In addition to the insulation liner being formed from an assembly of separate discrete interlocking panels discussed above, the base plate of the device comprising outer insulation segment 9 (FIGS. 3 and 13) and inner shield segment 11 and lid of the device comprising an outer insulation segment 8 (FIGS. 3 and 13) and inner shield segment 10 can also be formed from an assembly of interlocking panels. A similar interlocking feature as discussed for the insulation segment can be used for joining together the panels in the base plate so as to provide a tortuous path between the top face and bottom face of the base plate to inhibit heat loss and the containment of the exhaust gases. To provide thermal insulation to the top cover, an insulating outer lid can form part of the top cover. The base plate as shown in FIG. 13, can be formed from two plates, a graphite plate 11 which cooperates with the inner shield segment to house the reactant gases during the conversion process and an outer insulation segment 9 to provide thermal insulation during the conversion process. As with the base plate 9 and 11, the lid 8 and 10 can be formed from an assembly of a plurality of interlocked units.

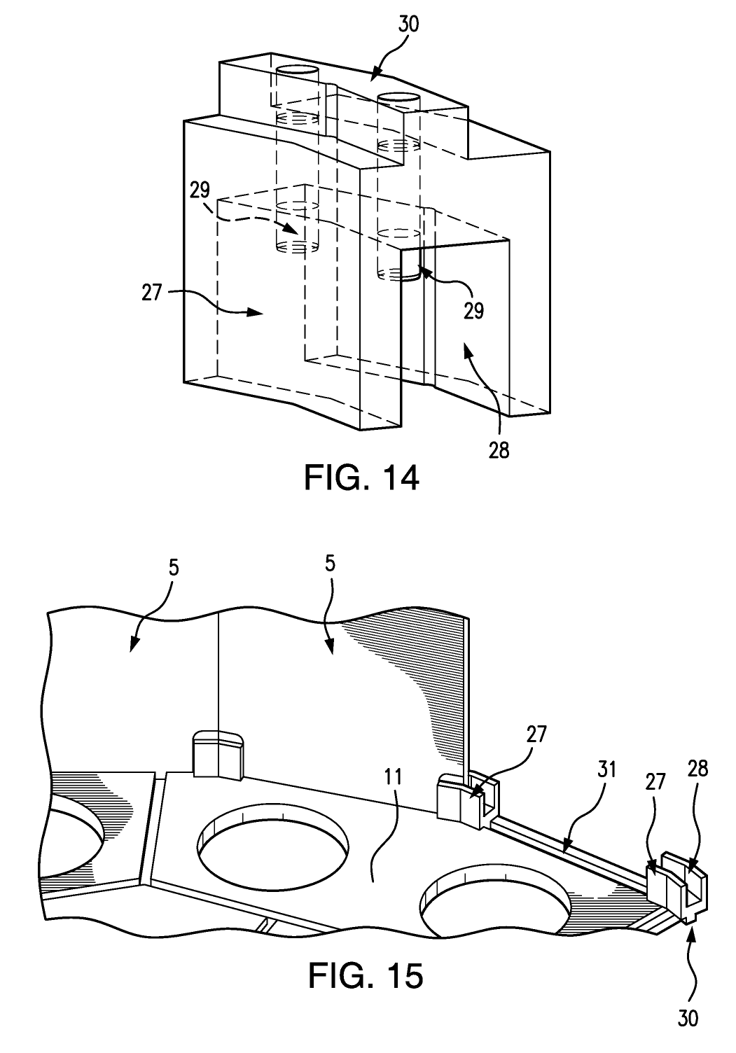

Referring to FIG. 14, a terminating (top or bottom) connector 27 is shown having a raised rib 30 on one side, which can be interfitted in groove 31 in base plate 11 (such as shown in FIGS. 13 and 15). A slot 28 on the opposite side of the connector 27 is configured to receive inner shield panels 5 and outer insulation panels 2. The same angle (e.g., about 162°) can exist between the channels in the terminating connector 27 shown in FIG. 14 as angle α of the middle connector 7. Pins 29, which project into channel 28 and can be fitted into slots 24 on inner shield panels 5, can be formed integrally with the body of connector 27, such as done with pins 23 in connectors 7.

Referring to FIG. 15, an example of how terminating connectors 27 can be fitted into bottom ring sub-assembly shield panels 5 and groove 31 of base plate 11 is shown. The terminating connector 27, such as shown in FIG. 14, can be inverted for interfitting of the rib 30 into groove 31 of base plate 11 as shown in FIG. 15.

Referring to FIG. 16, an example of a channel 115 created in a thermal converter by divider plates 32 is shown. The divider segment (e.g., a plurality of panels) can be arranged radially internal with respect to groove 31 (e.g., FIG. 15). Middle connectors 33 are used, at least in part, to join the divider panels 32. As illustrated at portion 321, the divider panels 32 can intersect to form an abutting stop where they meet each other without using a connector at the intersection, and they also can be joined by connectors 33 at other intersections to define an array of divider panels 32 that completely surrounds and defines at least one channel region 115.

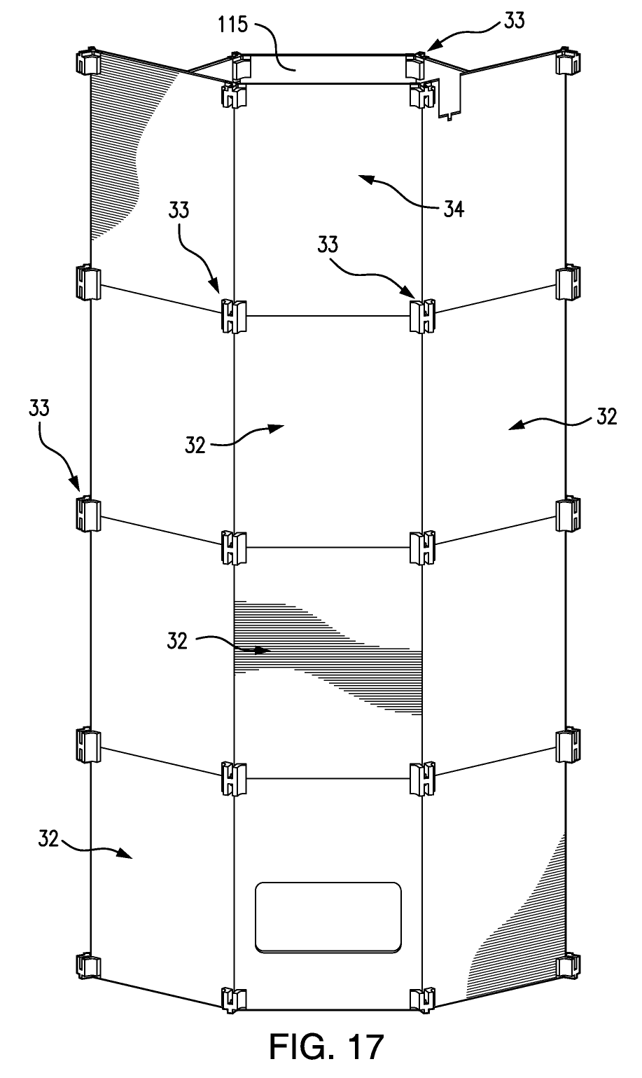

Referring to FIG. 17, a front perspective view is shown of channel 115 created in a thermal converter by divider panels 32 assembled into a divider panel sub-assembly 34 using divider panel middle connectors 33.

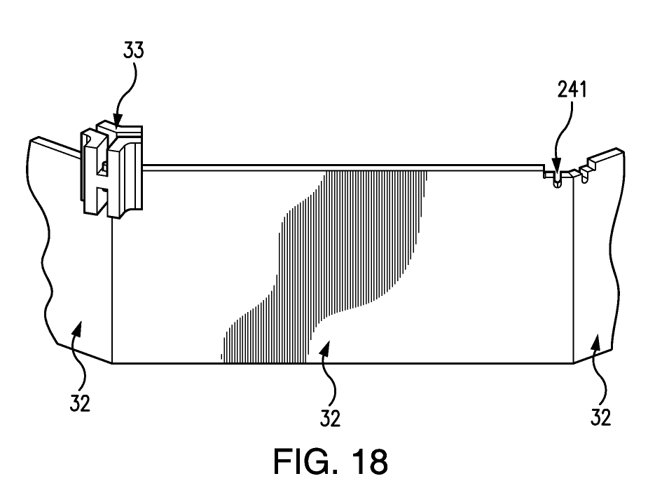

Referring to FIG. 18, channel divider panels 32 are shown interconnected using divider panel middle connector 33. The divider panels 32 have slots 241, which can function similar to slots 24 in shield panels 5 to receive pins on connectors (e.g., 33).

Referring to FIG. 19, a middle connector 33 for joining divider panels 32 is shown having slots 35 that receive divider panels 32, and pins 36 which vertically extend from the upper and lower surfaces of a Y-shaped bridge member 331. The pins 36 can be used to lock divider panels 32 into place when interfitted from above or below the connector 33. Pins 36 can be formed integrally with the body of connector 33, such as done with pins 23 in connectors 7 and pins 29 in terminating connector 27.

Referring to FIG. 20, several channel divider panels 32 of a portion of internal divider panel assembly 34 are shown interconnected to a base plate 11. Ring-patterned slots 38 and intersecting radially-extending slots 381 are located interior to outer groove 31 of base plate 11. Slots 38 and 381 are configured to receive terminating connectors 44 for installing the divider panels 32. Divider panel middle connectors 47 are used on the opposite top edge of divider panels 32 to continue the assemblage of divider panels in a vertical direction. At least one additional ring-patterned slot 37 can be located interior to ring-patterned slot 38, which also can be used to attach divider panels such as shown in other illustrations herein. In this manner, one more of the holes 52 for accommodating heater rods, for example, can be partially or completely surrounded with divider panels 32, such as shown in illustrations herein.

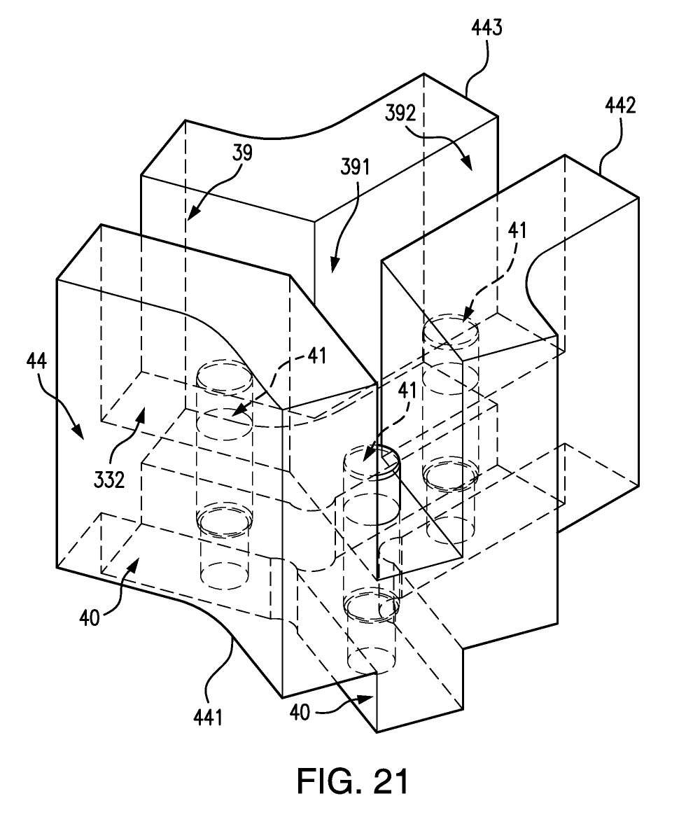

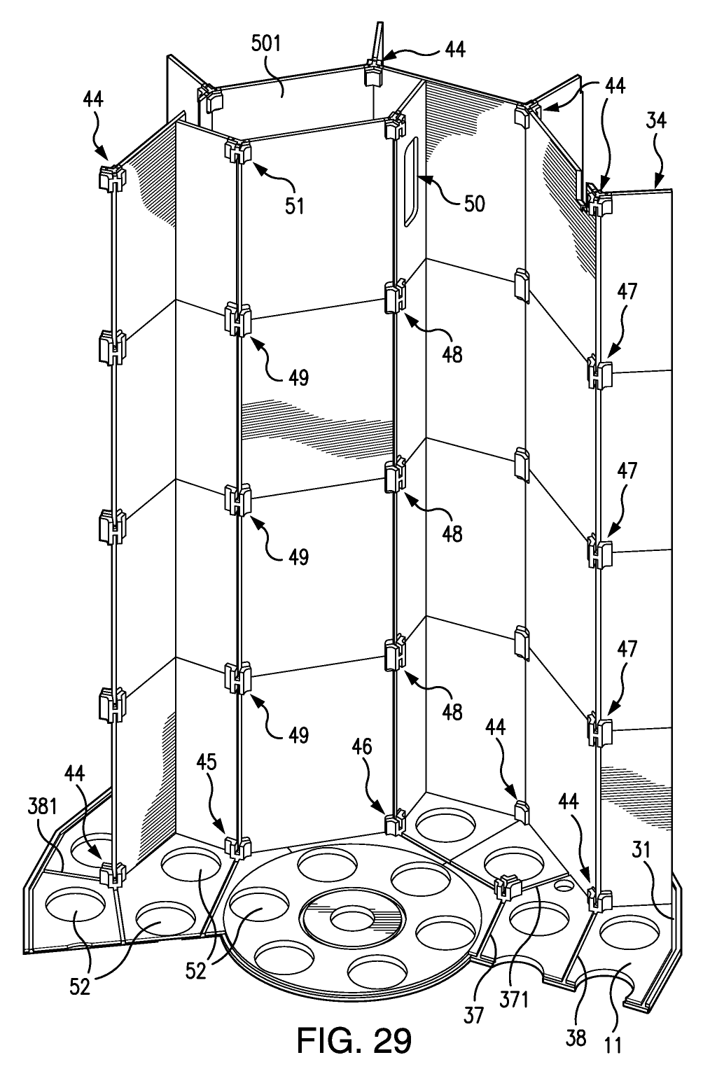

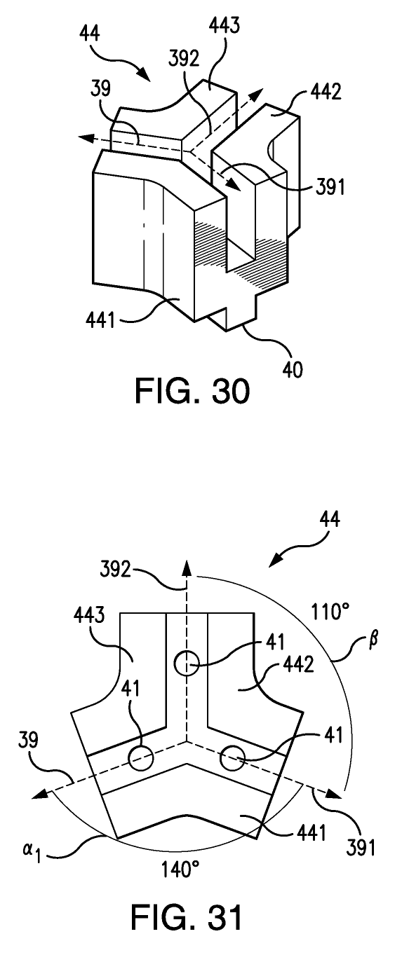

Referring to FIG. 21, terminating (top and bottom) connector 44 is shown having an angle formed by intersecting channels 39 and 391 of about 138° to about 142° (e.g., about 140°) and an angle formed by intersecting channels 39 and 392, and intersecting channels 391 and 392, of about 108° to about 112° (e.g., about 110°). In other examples, the angles could be other values, for instance, about 120° for both angles, or other values. Pins 41 extend from the upper surface of a Y-shaped bridge member 332 into channels 39, 391, and 392. Bridge member 332 interconnects portions 441, 442, and 443 of connector 44, which have inner facing vertical walls defining the channels 39, 391, and 392 with a bottom wall of the bridge member. The pins 41 can be used to lock divider panels 32 into place when interfitted from above the connector 44. Pins 41 can be formed integrally with the body of connector 44, such as done with pins 23 in connectors 7, pins 36 in middle connector 33, and pins 29 in terminating connector 27. Connector 44 has a rib 40 protruding from its lower side and opposite to the side having the channels 39, 391, and 392. The rib 40 can be shaped to correspond with slots 38 and 381 on the base plate 11. The rib 40 protruding from the lower side of connector 44 can be interfitted into slots 38 and 381 on base plate 11 to attach the connector 44 to the base plate 11. Rib 40 can have portions located opposite to and making angles corresponding to the indicated angles made by channels 39, 391, and 392 of connector 40. The rib 40 thus can be Y-shaped. FIG. 29 shows an intersection of slots 38 and 381 where the connector 44 can be used, for example, to connect divider panels 32 onto base plate 11. Connector 44 can be oriented when used wherein the portions of a Y-shaped rib 40 under channels 39 and 391 of connector 44 can be fitted into the ring-patterned slots 38, and the portion of rib 40 under channel 392 can be fitted into a radially-extending slot 381. Divider panels 32 can be fitted into channels 39, 391, and 392 of connector 44 from above. FIG. 30 shows connector 44 with the locations and directions of channels 39, 391, and 392 defined between portions 441, 442, and 443 indicated by the arrows. FIG. 31 is a top view of connector 44 which shows an angle α₁ (140° made between channels 39 and 391, and an angle β (110°) made between channels 391 and 392 (and similarly between channels 39 and 392).

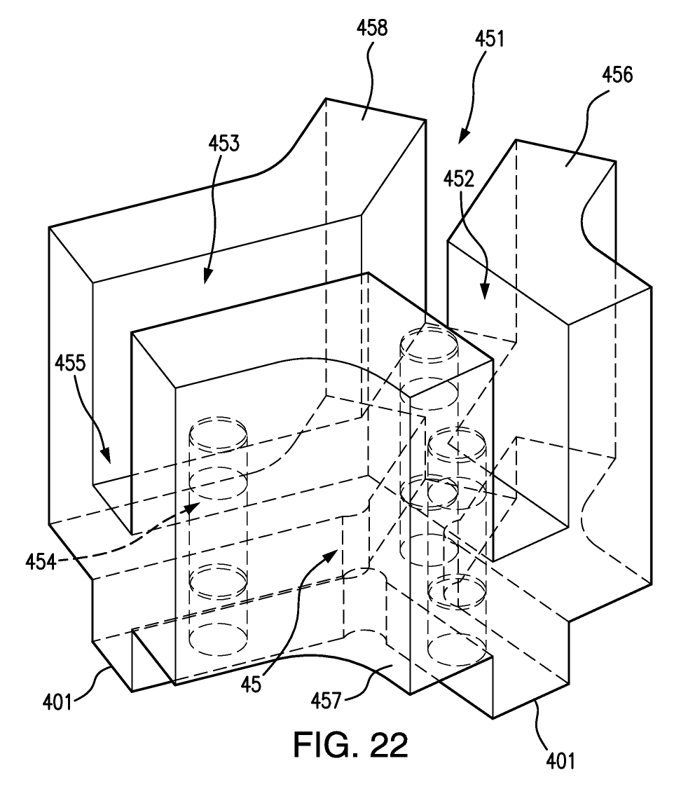

Referring to FIG. 22, a bottom connector 45 is shown having an angle formed by intersecting channels 451 and 452 of about 133° to about 137° (e.g., about 135°) and an angle formed by intersecting channels 451 and 453, and intersecting channels 452 and 453, of about 103° to about 107° (e.g., about 105°). Pins 454 project from the upper surface of a Y-shaped bridge member 455 into the channels 451, 452, and 453. Bridge member 455 interconnects portions 456, 457, and 458 of connector 45, which have inner facing vertical walls defining the channels 451, 452, and 453 with a bottom wall of the bridge member. The pins 454 can be used to lock divider panels 32 into place when interfitted from above the connector 45. Pins 454 can be formed integrally with the body of connector 45, such as done with pins 41 in connector 44, and other similar pins indicated herein. Connector 45 has a rib 401 protruding from its lower side and opposite to the side having the channels 451, 452, and 453. The rib 401 can be shaped to correspond with slots on the base plate 11. The rib 401 protruding from the lower side of connector 45 can be interfitted into slots 37 and 371 on base plate 11 to attach the connector 45 to the base plate 11. Rib 401 can have portions located opposite to and making angles corresponding to the indicated angles made by channels 451, 452, and 453 of connector 45. The rib 401 thus can be Y-shaped. FIG. 29 shows an intersection of slots 37 and 371 where the connector 45 can be used, for example, to connect divider panels 32 onto base plate 11. Connector 45 can be oriented when used wherein the portions of a Y-shaped rib 401 under channels 451 and 452 of connector 45 can be fitted into the ring-patterned slots 37, and the portion of rib 401 under channel 453 can be fitted into a radially-extending slot 371. Divider panels 32 can be fitted into channels 451, 452, and 453 of connector 45 from above.

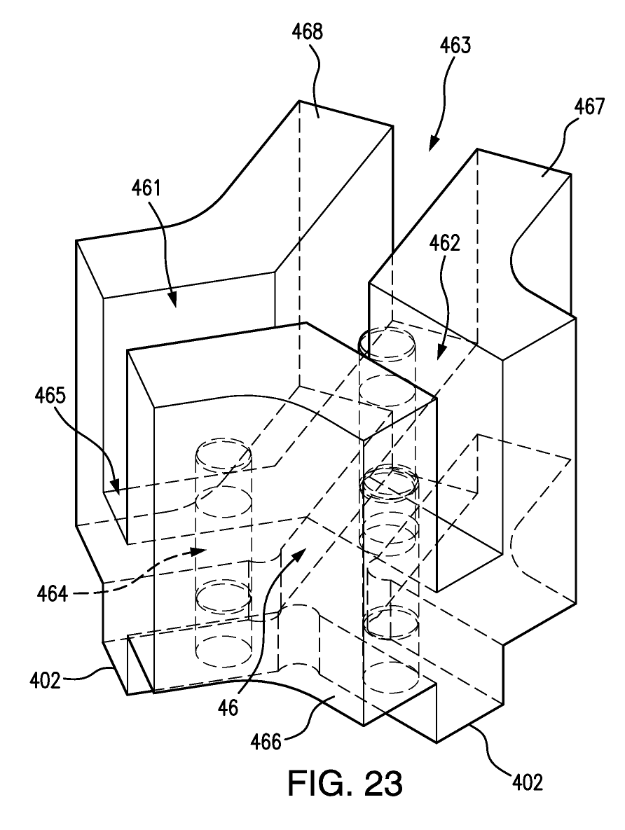

Referring to FIG. 23, a bottom connector 46 is shown having an angle formed by intersecting channels 461 and 462 of about 128° to about 132° (e.g., about 130°) and an angle formed by intersecting channels 461 and 463, and intersecting channels 462 and 463, of about 108° to about 112° (e.g., about 110°). Pins 464 project from the upper surface of a Y-shaped bridge member 465 into channels 461, 462, and 463. Bridge member 465 interconnects portions 466, 467, and 468 of connector 46, which have inner facing vertical walls defining the channels 461, 462, and 463 with a bottom wall of the bridge member. The pins 464 can be used to lock divider panels 32 into place when interfitted from above the connector 46. Pins 464 can be formed integrally with the body of connector 46, such as done with pins 41 in connector 44, and other similar pins indicated herein. Connector 46 has a rib 402 protruding from its lower side and opposite to the side having the channels 461, 462, and 463. The rib 402 can be shaped to correspond with slots on the base plate 11. The rib 402 protruding from the lower side of connector 46 can be interfitted into slots 37 and 371 on base plate 11 to attach the connector 46 to the base plate 11. Rib 402 can have portions located opposite to and making angles corresponding to the indicated angles made by channels 461, 462, and 463 of connector 46. The rib 402 thus can be Y-shaped. FIG. 29 shows an intersection of slots 37 and 371 where the connector 46 can be used, for example, to connect divider panels 32 onto base plate 11. Connector 46 can be oriented when used wherein the portions of a Y-shaped rib 402 under channels 461 and 462 of connector 45 can be fitted into the ring-patterned slots 37, and the portion of rib 402 under channel 463 can be fitted into a radially-extending slot 371. Divider panels 32 can be fitted into channels 461, 462, and 463 of connector 46 from above. Different radially extending slots 371 on base plate 11 can make the same or different angles with slots 37, and connectors 45 and 46 can have different rib angles to correspond to any differences, if present.

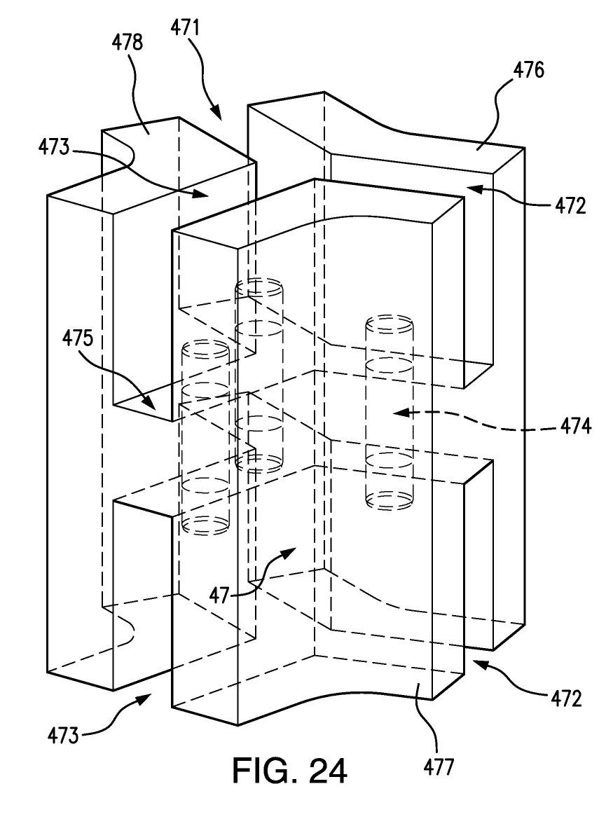

Referring to FIG. 24, a middle connector 47 is shown having an angle formed by intersecting channels 471 and 472 of about 138° to about 142° (e.g., about 140°) and an angle formed by intersecting channels 471 and 473, and intersecting channels 472 and 473, of about 108° to about 112° (e.g., about 110°). Pins 474 project from the upper and lower surfaces of a Y-shaped medial bridge member 475. Bridge member 475 interconnects portions 476, 477, and 478 of connector 47, which have inner facing vertical walls defining the channels 471, 472, and 473 with a bottom wall of the bridge member. The angles of the channels can be the same on both sides of bridge member 475. The pins 474 can be used to lock divider panels 32 into place when interfitted into the channels from above or below the connector 47. Pins 474 can be formed integrally with the body of connector 47, such as done with such as done with pins 23 in connectors 7 and pins 36 in connector 33, and other similar pins indicated herein. FIG. 29 shows an intersection of ring shape patterned slots 38 and radially extending slots 381 where the connector 47 can be used, for example, to connect middle divider panels 32 where stacked above panel 11. Connector 47 can be oriented when used wherein channels 471 and 472 of connector 47 can be fitted with divider panels 32 where stacked in alignment above ring-patterned slots 38 of panel 11, and channel 473 can be fitted with a divider panel 32 where stacked in alignment above radially-extending slot 381 of panel 11.

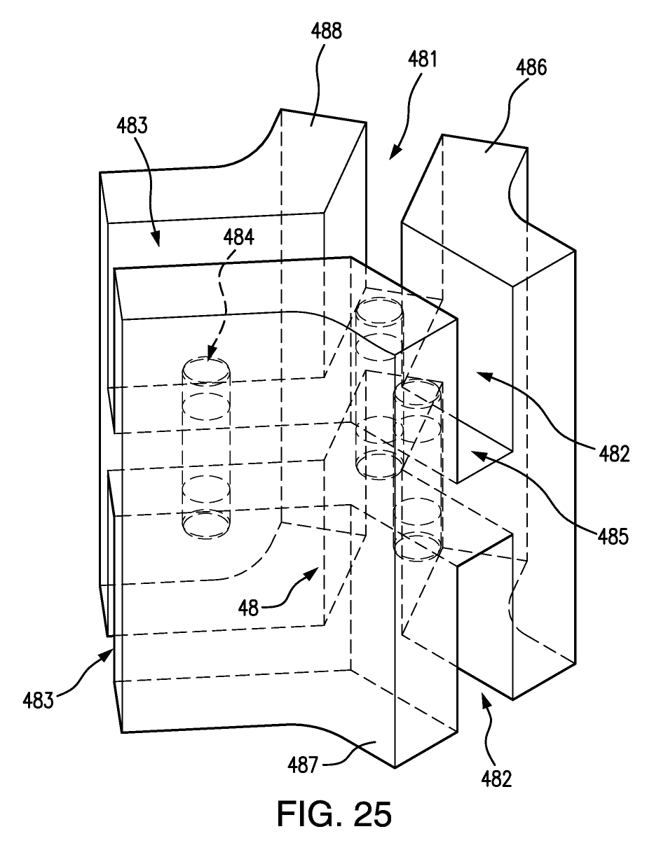

Referring to FIG. 25, a middle connector 48 is shown having an angle formed by intersecting channels 481 and 482 of about 128° to about 132° (e.g., about 130°) and an angle formed by intersecting channels 481 and 483, and intersecting channels 482 and 483, of about 108° to about 112° (e.g., about 110°). Pins 484 project from the upper and lower surfaces of a Y-shaped medial bridge member 485. Bridge member 475 interconnects portions 486, 487, and 488 of connector 48, which have inner facing vertical walls defining the channels 481, 482, and 483 with a bottom wall of the bridge member. The angles of the channels can be the same on both sides of bridge member 485. The pins 484 can be used to lock divider panels 32 into place when interfitted from above or below the connector 48. Pins 484 can be formed integrally with the body of connector 48, such as done with such as done with pins 23 in connectors 7 and pins 36 in connector 33, and other similar pins indicated herein. FIG. 29 shows an intersection of ring shape patterned slots 37 and radially extending slots 371 where the connector 48 can be used, for example, to connect divider panels 32 where stacked above base plate 11. Connector 48 can be oriented when used wherein channels 481 and 482 of connector 48 can be fitted with divider panels 32 where stacked in alignment above ring-patterned slots 37 of panel 11, and channel 483 can be fitted with a divider panel 32 where stacked in alignment above radially-extending slot 371 of panel 11.

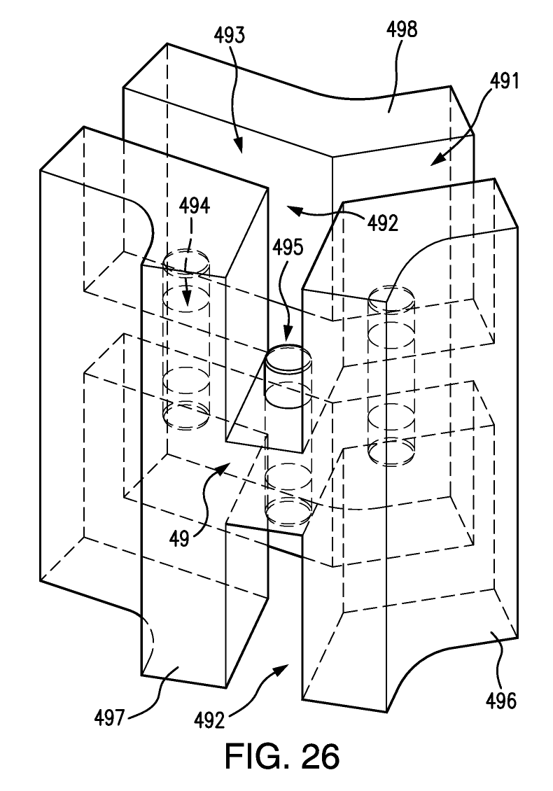

Referring to FIG. 26, a middle connector 49 is shown having an angle formed by intersecting channels 491 and 492 of about 133° to about 137° (e.g., about 135°) and an angle formed by intersecting channels 491 and 493, and intersecting channels 492 and 493, of about 103° to about 107° (e.g., about 105°). Pins 494 project from the upper and lower surfaces of a Y-shaped medial bridge member 495. Bridge member 495 interconnects portions 496, 497, and 498 of connector 49, which have inner facing vertical walls defining the channels 491, 492, and 493 with a bottom wall of the bridge member. The angles of the channels can be the same on both sides of bridge member 495. The pins 494 can be used to lock divider panels 32 into place when interfitted from above or below the connector 49. Pins 494 can be formed integrally with the body of connector 49, such as done with such as done with pins 23 in connectors 7 and pins 36 in connector 33, and other similar pins indicated herein. FIG. 29 shows an intersection of ring shape patterned slots 37 and radially extending slots 371 where the connector 49 can be used, for example, to connect divider panels 32 on base plate 11. Connector 49 can be oriented when used wherein channels 491 and 492 of connector 49 can be fitted with divider panels 32 where stacked in alignment above ring-patterned slots 37 of plate 11, and channel 493 can be fitted with a divider panel 32 where stacked in alignment above radially-extending slot 371 of plate 11. As indicated, different radially extending slots 371 on base plate 11 can make the same or different angles with slots 37, and, correspondingly, middle connectors 48 and 49 also can have different slot angles to correspond to such differences, if present.

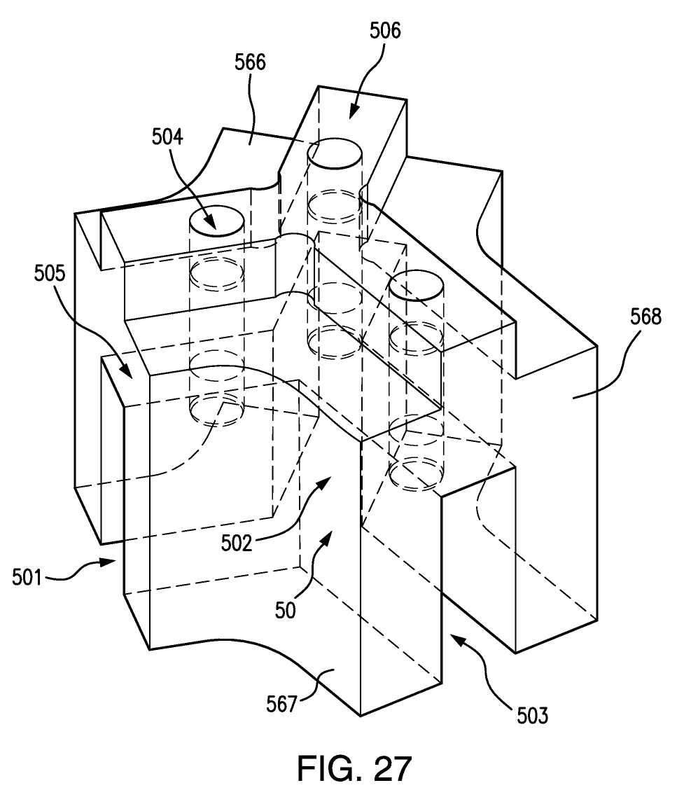

Referring to FIG. 27, a top connector 50 is shown having an angle formed by intersecting channels 501 and 502 of about 128° to about 132° (e.g., about 130°) and an angle formed by intersecting channels 501 and 503, and intersecting channels 502 and 503, of about 108° to about 112° (e.g., about 110°). Pins 504 project from the upper surface of a Y-shaped bridge member 505. Bridge member 505 interconnects portions 566, 567, and 568 of connector 50, which have inner facing vertical walls defining the channels 501, 502, and 503 with a bottom wall of the bridge member. The pins 504 can be used to lock divider panels 32 into place when interfitted from below the connector 50. Pins 504 can be formed integrally with the body of connector 50, such as done with pins 41 in connector 44, and other similar pins indicated herein. A rib 506 protruding from the upper side of connector 50 can be interfitted into slots on top plate 10 (shown in FIG. 3), which can be similar to slots 37 in base plate 11, to attach the connector 50 to a top base plate. The rib 506 can be shaped to correspond with the slots in the top base plate 10. Rib 506 can have portions located opposite to and making angles corresponding to the indicated angles made by channels 501, 502, and 503 of connector 50. Rib 506 thus can be Y-shaped. FIG. 29 shows connector 50 used to connect divider panels 32 using the slots 501, 502, and 503 and pins 504 at its bottom side, and ribbed side 506 is available at the top side of connector 50 for attachment to a top plate. The ribbed side (506) of the connector 50 can be oriented in a similar configuration with respect to slots in the top plate 10 to correspond to the indicated arrangement of the ribbed side (402) of bottom connector 46 on base plate 11.

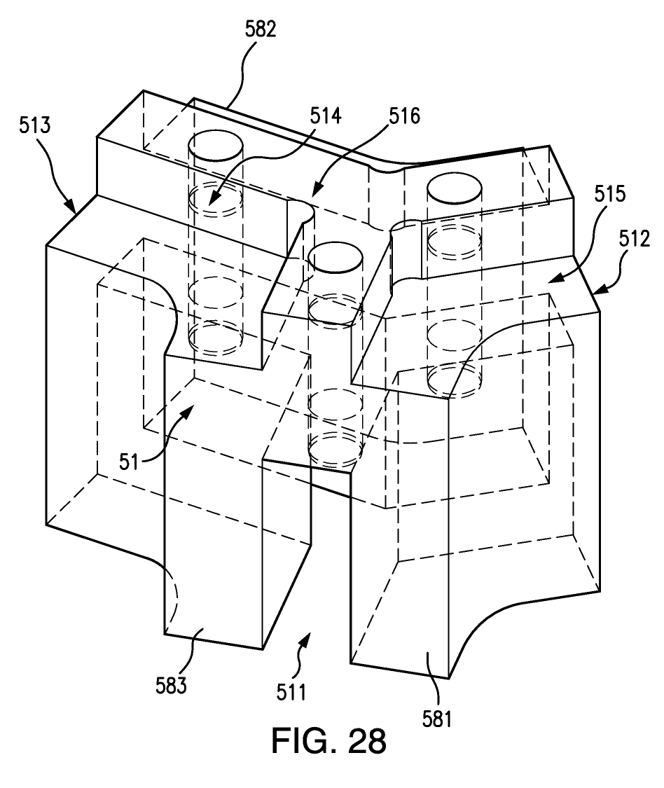

Referring to FIG. 28, a top connector 51 is shown having an angle formed by intersecting channels 511 and 512 of about 133° to about 137° (e.g., about 135°) and an angle formed by intersecting channels 511 and 513, and intersecting channels 512 and 513, of about 103° to about 107° (e.g., about 105°). Pins 514 project from the upper surface of a Y-shaped bridge member 515. Bridge member 515 interconnects portions 581, 582, and 583 of connector 51, which have inner facing vertical walls defining the channels 511, 512, and 513 with a bottom wall of the bridge member. The pins 514 can be used to lock divider panels 32 into place when interfitted from below the connector 51. Pins 514 can be formed integrally with the body of connector 51, such as done with pins 41 in connector 44, and other similar pins indicated herein. A rib 516 protruding from the upper side of connector 51 can be interfitted into slots on top plate 10 (shown in FIG. 3), which can be similar to slots 37 in base plate 11, to attach the connector 51 to a top plate. The rib 516 can be shaped to correspond with the slots in the top plate 10. Rib 516 can have portions located opposite to and making angles corresponding to the indicated angles made by channels 511, 512, and 513 of connector 51. Rib 516 thus can be Y-shaped. FIG. 29 shows connector 51 used to connect divider panels 32 using the slots 511, 512, and 513 and pins 514 at its bottom side, and ribbed side 516 is available at the top side of connector 51 for attachment to a top plate. The ribbed side (516) of the connector 51 can be oriented in a similar configuration with respect to slots in the top plate 10 to correspond to the indicated arrangement of the ribbed side (402) of bottom connector 46 on base plate 11. Top plate 10 can have different radially extending slots similar to slots 371 on base plate 11 to make the same or different angles with slots similar to slots 37 on base plate 11, wherein connectors 50 and 51 can have different rib angles and slot angles to correspond to such differences, if present.

Referring to FIG. 29, an inner divider segment assembly 34 is shown having features such as discussed in some of the foregoing figures. Channel 501 is defined by inner shield segment panels 32 stacked in four ring-shaped sub-assemblies and joined by bottom connectors including connectors 44, 45, and 46, middle connectors including connectors 47, 48, and 49, and top connectors including connectors 44, 50, and 51.

Another feature of a containment system of the present invention relates to panel connectors, which can be used to join panels, divider panels, and the like. The panel connectors can have designs such as, but not limited to, the connectors shown in FIGS. 9, 14, 19, 21-28, 30, and 31. As indicated in discussions of FIGS. 2-9 and 14-31, for example, the connectors can include types falling into at least categories of terminating (top and/or bottom) connectors and middle connectors. Terminating connectors can be used, for example, to connect one or more panels to a base plate. Middle connectors can be used, for example, to connect panel to panel, or panel to panels, or panels to panels. For sake of simplicity, both categories, inclusive of those used for joining panels or divider plates, generally may be referred to as panel connectors and can share some features in common. Some differences in the connectors, which are related to the intended point of use in the panel assemblies, also are illustrated herein in some of the indicated figures.

The panel connectors for connecting together two or more panels, for example, can have at least first and second pairs of opposing walls which form intersecting grooves. The first pair of opposing walls can each comprise a planar inner surface, and the inner surfaces of the first pair of opposing walls can be oriented parallel to one another. A bottom wall comprises a first planar surface that intersects with each of the planar inner surfaces of the first pair of opposing walls such that the first pair of opposing walls and the bottom wall together form a first groove having planar inner side-walls normal to a planar bottom surface. The second pair of opposing walls can each comprise a planar inner surface, and the inner surfaces of the second pair of opposing walls can be oriented parallel to one another and intersecting the first planar surface of the bottom wall such that the second pair of opposing walls and the bottom wall together form a second groove having planar inner side-walls normal to a planar bottom surface. The first groove can intersect the second groove at an intersection of grooves, wherein the bottom surface of the first groove is co-planar with the bottom surface of the second groove. Neither of the opposing walls of the first pair of opposing walls is co-planar with either of the opposing walls of the second pair of opposing walls. The first pair of opposing walls, the second pair of opposing walls, and the bottom wall all can comprise a carbon-based material, such as, for example, graphite. The panel connector can further have the first groove and the second groove angled with respect to one another and the intersection of grooves comprises a corner. The intersection of grooves can comprise, for example, a curved surface. The panel connector further can have the first pair of opposing walls and the bottom wall together having a [symbol] -shaped cross-section when taken perpendicular to the first groove, and the second pair of opposing walls and the bottom wall together can have a [symbol] -shaped cross-section when taken perpendicular to the second groove. Panel connectors which can have some or all of these features can include the connectors, such as shown in FIGS. 9, 14, 19, 21-28, 30, and 31, or other designs.

The panel connector, in another example, further can have a bottom wall which has a second planar surface opposite the first planar surface, and the panel connector can further comprise third and fourth pairs of opposing walls. The third pair of opposing walls can each comprise a planar inner surface and can be oriented parallel to one another, wherein the planar inner surfaces of the third pair of opposing walls intersect the second planar surface of the bottom wall to form a third groove that faces away from the first groove. The fourth pair of opposing walls can each comprise a planar inner surface and can be oriented parallel to one another, wherein the planar inner surfaces of the fourth pair of opposing walls intersect the second planar surface of the bottom wall to form a fourth groove that faces away from the second groove. Further, the third groove can intersect the fourth groove at a second intersection of grooves, and the bottom surface of the third groove can be co-planar with the bottom surface of the fourth groove. Neither of the opposing walls of the third pair of opposing walls is co-planar with either of the opposing walls of the fourth pair of opposing walls. The third pair of opposing walls and the fourth pair of opposing walls can comprise a carbon-based material, such as graphite. The first pair of opposing walls, the bottom wall, and the third pair of opposing walls together can have, for example, an H-shaped cross-section when taken perpendicular to the first and third grooves, and the second pair of opposing walls, the bottom wall, and the fourth pair of opposing walls together also can have an H-shaped cross-section when taken perpendicular to the second and fourth grooves. These connectors generally can be used, for example, as middle connectors, such as shown in FIG. 9. As indicated, these types of middle connectors can be used, for example, to connect inner shield panels, such as shown in FIGS. 2 and 3.

The panel connector, in another example, further can have a bottom wall which has a rib opposite the first planar surface. The rib can be interfitted, for example, into grooves on a base plate. This connector generally can be used, for example, as a terminating connector, such as shown in FIG. 14, for connecting panels to a base plate, such as shown in FIG. 15.

The panel connectors, in other examples, further can have Y-shaped intersecting grooves or channels defined by three pairs of inner facing vertical walls on at least one side of the connectors, such as shown in FIGS. 19, 21-28, 30, and 31. These connectors further include a third pair of opposing walls, on the same side of the connector as the first and second pairs of opposing walls, wherein the three pairs of opposing walls, together with the bottom wall, define three grooves or channels that intersect to define a Y-shaped groove or channel pattern. In some of these designs which are related to middle connectors for connecting panels to panels (divider plates to plates), such as shown in FIGS. 17, 20, and 29, the Y-shaped grooves are provided on both opposite sides of the connector body, such as shown in FIGS. 19 and 24-28. In some other designs which are related to terminating connectors for connecting panels (divider panels) to a base plate, such as shown in FIGS. 17, 20, and 29, a Y-shaped groove is provided on one side of the connector body, and a corresponding Y-shaped rib is provided on the opposite side of the connector body, such as shown in FIGS. 21-23 and 30-31.

Any of the above-indicated panel connectors further can have at least one integral connector pin which projects from at least one bottom wall into a groove, or at least one integral connector pin can project from a bottom wall of each of the grooves of the connector, or multiple integral connector pins (e.g., 2, 3, 4, or more) can project from a bottom wall of each of the grooves of the connector, such as shown, for example, in FIGS. 9, 19, and 21-28. The pins can project partially or fully into the grooves or channels defined by the inner walls and bottom wall of the connector, such as, for example, at least about 3%, or about 3% to about 100%, or from about 5% to about 30%, or from about 7% to about 25%, or from about 10% to at least about 20%, or other values relative to the total groove or channel depth. As indicated, the pins, when included, can be shaped and sized to be interfittable into aligned slots on panels (see, e.g., FIG. 10).

The present invention further relates to an apparatus for performing a thermally controlled gas phase chemical process using or producing gases, wherein the apparatus comprises a chamber and the insulation segment and/or shield segment and/or divider segment of the present invention housed within the chamber and comprising carbon based materials, and optionally, wherein the insulation segment and/or shield segment and/or divider segment comprises an assembly of a plurality of interlocked units (e.g. panels). By “interlocked” is meant that adjacent units are joined in a manner that prevents or restricts relative motion in at least one axis (or at least two axis). The interlocked panels of the insulation segment and/or shield segment and/or divider segment can provide adequate gas and/or heat retention with sufficient structural strength and stiffness to the assembled insulation segment and/or shield segment and/or divider segment to maintain its shape at high reaction temperatures (such as over 1,000 degrees C.).

When a plurality of panels are joined together in interlocking fashion, the joints formed by interlocking successive units (e.g., panels) define a tortuous path between the interior and exterior surface of the insulation segment and/or shield segment and/or divider segment and thereby inhibit heat losses from within the segments and the escape of the gases. Unlike prior systems that utilize insulation material, if any one area of the insulation segment and/or shield segment and/or divider segment is damaged or degrades in the present invention, the entire body does not need to be replaced and the worn or damaged area can be replaced without the need to replace any undamaged or unworn panels of the containment system of the present invention.

As an option, when the insulation segment and/or shield segment and/or divider segment comprises panels, at least one side of each of the panels may be formed with an interlocking feature so as to co-operate with a complementary interlocking feature of an adjacent panel or panels. Optionally, all sides of the panel(s) may be formed with interlocking features.

Optionally, the interlocking feature of any segment of the present invention, can comprise a tongue-like projection receivable in a complementary groove or recess of an adjacent panel. The tongue and groove assembly at the joints defines a tortuous path between the interior and exterior of the assembled insulation segment and/or shield segment and/or divider segment for the reaction gasses. Such a tortuous path at the joints avoids the formation of straight through slots at the joints between adjacent abutting panels where the gasses or heat can easily leak through causing undesirable losses.

Alternatively, the panels may comprise complementary grooves or recesses which in adjacent panels co-operate to form a channel to receive a key to interlock the adjacent panels together. The panels may be snap-fitted together to prevent the panels from disassembling.

In addition to providing insulating properties, the panels should withstand the corrosive nature of the gases during the production of semi-conductor materials. The containment system of the present invention is capable of operating successfully in a CVD Reactor and/or a Thermal Convertor.

The apparatus of the present invention may be a reactor for chemical vapour deposition of a semiconductor material onto a heating source by the thermal decomposition of a gaseous precursor compound of the semiconductor material. If the semiconductor material is silicon the gaseous precursor compound may comprise a silane gas, for example, monosilane, disilane or mixtures thereof. Alternatively, the gaseous precursor may comprise a halosilane gas, for example trichlorosilane. The apparatus may be a convertor for the production of a gaseous precursor compound of a semiconductor material for use in a reactor.

The present invention, as an option, can include a rigid-flexible hybrid material for a component of the containment system (e.g., insulation segment, shield segment, and/or divider segment). The rigid-flexible hybrid material can be, for instance, a rigid-flexible hybrid insulation material that can include at least one rigid insulation layer bonded to at least one flexible insulation layer, where the rigid insulation layer and the flexible insulation layer comprise carbon based materials. Flexible insulation is defined as any insulation than can be bent around a 10 inch (25.4 cm) diameter form and still be usable as an insulating material. Rigid insulation is defined as any insulation with a flexural strength of at least approximately 10 psi.

A rigid-flexible hybrid material offers significant advantages over the use of solely either the rigid insulation or the flexible insulation. Flexible insulation has excellent thermal insulation properties, but lacks the strength in its structure to be useful in applications requiring a solid form. Rigid insulation has excellent structural properties, but is less effective as an insulation than flexible insulation.

Both the rigid and flexible insulation may be formed from any appropriate carbon fiber precursor, including, but not limited to Rayon, PAN, pitch, or other suitable carbon precursor material.

The sum of the flexible insulation thicknesses can be at least approximately 0.25 inch (0.6 cm). The two forms of insulation may be bonded to one another in any suitable manner.

The rigid and flexible layers may be assembled in any variety of alternating relationships and may be assembled in either a liquid or dry form. The individual rigid and flexible layers may have a variety of thicknesses. The sum of the total flexible layer thicknesses can be at least approximately 0.25 inch (0.6 cm) thick. The total thickness of the combined layers can range from approximately 0.25 (0.6 cm) to 9.0 inches (22.9 cm).

The layered insulation material may also include at least one layer of flexible graphite (also known as graphite foil). The rigid and flexible layers and the at least one graphite foil layer may be assembled in any variety of alternating relationships.

The layered insulation material may also include at least one layer of carbon fiber composite (CFC) material. The rigid and flexible layers and the at least one CFC layer may be assembled in any variety of alternating relationships.

The layered insulation material may include at least one layer of graphite foil and one layer of CFC. The rigid and flexible layers and the at least one graphite foil and at least one CFC layer may be assembled in any variety of alternating relationships.

The layered insulation material may also include at least one layer of graphite paint. The rigid and flexible layers and the at least one graphite paint layer, in combination with or in place of at least one graphite foil layer, may be assembled in any variety of alternating relationships.

The layered materials may be purified using temperature, temperature and vacuum, or temperature and halogen gases. After the layers are assembled, the layered insulation material may be machined into a variety of configurations.

In more detail, and as an example, the rigid-flexible insulative hybrid material 1 includes at least one rigid insulation layer 3 bonded to at least one flexible insulation layer 2, wherein the rigid insulation layer 3 and the flexible insulation layer 2 comprise carbon based material. The sum of the flexible insulation thicknesses can be at least approximately 0.25 inch (0.6 cm). Rigid insulation is defined as any insulation with a flexural strength of at least approximately 10 psi. The rigid insulation material 3 may be formed from any appropriate carbon fiber precursor, including, but not limited to, Rayon, PAN, pitch, or other suitable carbon precursor material. In addition, fillers, such as carbon black particles, coke particles, and/or ceramic fibers may be introduced into the flexible insulation materials. Moreover, the rigid insulation material 2 may have a density ranging from approximately 0.1 to 0.25 g/cc.

Flexible insulation 2 is defined as any insulation that can be bent around a 10 inch diameter form and still be usable as an insulating material. The flexible insulation material 2 may be formed from any appropriate carbon fiber precursor, including, but not limited to, Rayon, PAN, pitch, or other suitable carbon precursor material. The flexible insulation material may be formed from carbon fiber precursors of varying thicknesses, ranging from 0.1 inches (0.3 cm) to 2.0 inches (5.1 cm). In addition, fillers may be introduced into the flexible insulation materials. The flexible insulation material may comprise carbon fibers with a Denier or linear mass density ranging from approximately 1.0 to 50 Denier. Likewise, the flexible insulation material may have a density ranging from approximately 0.05 to 0.15 g/cc.

The rigid insulation layer 3 material and flexible insulation layer 2 material may be bonded to one another to form a laminated structure in any suitable manner. Examples of forming the laminated structure include, but not limited to, gluing the flexible insulation material to the rigid board using specially adapted high temperature glues/adhesives or resins or cements. Other bonding techniques include, using a vacuum pressure to draw the fibers in the flexible insulation material towards the rigid board. In one exemplarily technique as described in U.S. Pat. No. 6,248,677 (Dowding, L. D), a slurry containing the carbon fibers is poured over the rigid board material contained in a suitable mould and a vacuum pressure is applied to draw the fibers in the slurry towards the rigid board. As the fibers are pulled towards the rigid board, they become sufficiently entangled to form the flexible insulating layer. Thereafter, the composite material is removed from the mould and left to dry to form the laminated structure. The rigid insulation layer material and the flexible insulation layer material can be bonded together by an adhesive, e.g. a mixture of a phenolic resin and corn syrup. This adhesive mixture may be diluted with water to aid its application. The bonding agent can then be cured to harden the resin (cross-linking the polymeric chains in the bonding agent) at temperatures in the range 100° C. to 250° C. as is commonly known in the art to form a green body. The bonded layers in its green state can then be heat treated in an inert atmosphere such as argon or nitrogen to temperatures in excess of 1000° C. to improve the properties of the insulation material as well to carbonise the cured resin so forming a carbon bond holding the layers of insulation together. Other bonding agents or carbon precursors having sufficient adhesive properties to bond the insulation layers together in its green state as well have the ability to carbonise to form a carbon bond when heat treated at elevated temperatures commonly known in the art can be used. The other bonding agents include, but not limited to, pitch or tar. The rigid and flexible materials may be formed from different carbon precursors such as rayon-derived carbon fiber, pitch-derived carbon fiber, and PAN-derived carbon fiber.

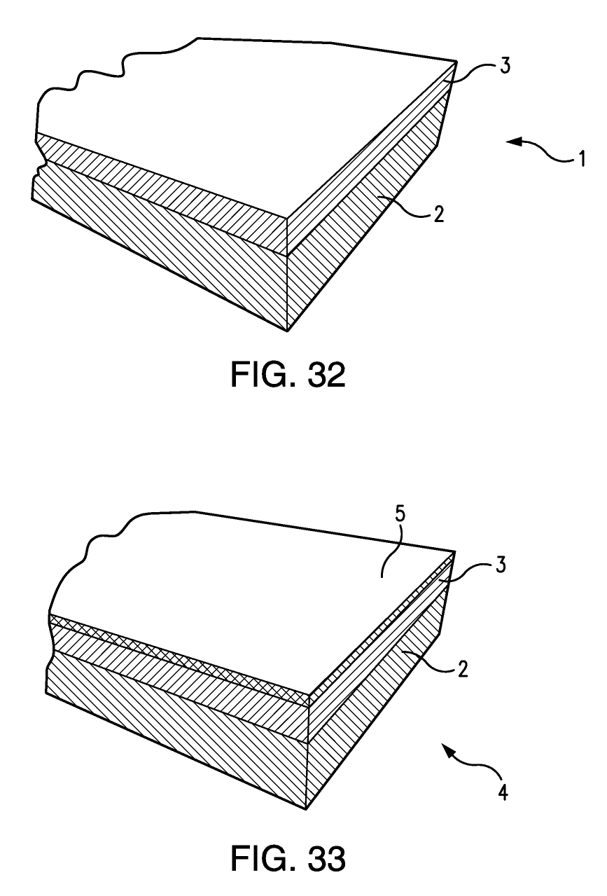

The rigid and flexible layers may be assembled in any variety of alternating relationships and may be assembled in either a liquid or dry form. FIG. 32 illustrate one example of the layered insulation material formed from rigid 3 and flexible 2 layers. In another example, the layers are arranged in a rigid-flexible-flexible-flexible-rigid configuration. In yet another example, the layers are arranged in a flexible-rigid-flexible-rigid-flexible configuration. The individual rigid and flexible layers can have a variety of thicknesses. The sum of the total flexible layer thicknesses can be at least approximately 0.25 inch (0.6 cm) thick. The total thickness of the combined layers can, for instance, range from approximately 0.25 (0.6 cm) to 9.0 inches (22.9 cm).

The layered insulation material 4 may also include at least one layer of flexible graphite 5, also known as graphite foil, material (see FIG. 33). Graphite foil is commonly manufactured from mineral graphite (expandable flake graphite). Graphite foil is an excellent sealing material and can be used for making chemical and high temperature resistant gaskets, sealing parts, compression packing, etc. Using its directional heat conductivity characteristics, graphite foil is often used as liners in industrial furnaces, as well as in electronic devices to control and spread heat flow. Graphite foil has an apparent density of at least 1.00 to 1.25 g/cc. The graphite foil layer may have a thickness ranging from 0.010 (0.0254 cm) to 0.25 inches (0.6 cm). The rigid 3 and flexible 2 layers and the at least one graphite foil layer may be assembled in any variety of alternating relationships. FIG. 33 illustrates one example of the layered insulation material 4 formed from rigid 3, flexible 2, and graphite foil 5 layers. In another example, the layers are arranged in a graphite foil-rigid-flexible-graphite foil-flexible-flexible-rigid configuration. In yet another embodiment, the layers are arranged in a graphite foil-flexible-rigid-flexible-rigid-flexible-graphite foil configuration.

The layered insulation material may also include at least one layer of carbon fiber composite (CFC) material. CFC material is a high strength two-directional fiber reinforced composite material that is useful in stringent structural and high temperature applications. The weave construction of CFC materials impart an excellent through-the-thickness thermal properties and a superior insulating qualities. CFC has an apparent density of at least 1.0 g/cc to 1.6 g/cc. The CFC layer may have a thickness ranging from 0.0625 inch (0.16 cm) to 0.5 inch (1.3 cm). The rigid and flexible layers and the at least one CFC layer may be assembled in any variety of alternating relationships. The layers can be arranged in a rigid-flexible-flexible-flexible-rigid-CFC configuration. As another example, the layers can be arranged in a flexible-rigid-flexible-rigid-flexible-CFC configuration.

The layered insulation material may include at least one layer of graphite foil and one layer of CFC. The rigid and flexible layers and the at least one graphite foil and at least one CFC layer may be assembled in any variety of alternating relationships. In one example, the layers can be arranged in a graphite foil-rigid-flexible-graphite foil-flexible-flexible-rigid-CFC configuration. In another example, the layers can be arranged in a graphite foil-flexible-rigid-graphite foil-flexible-rigid-flexible-CFC configuration.

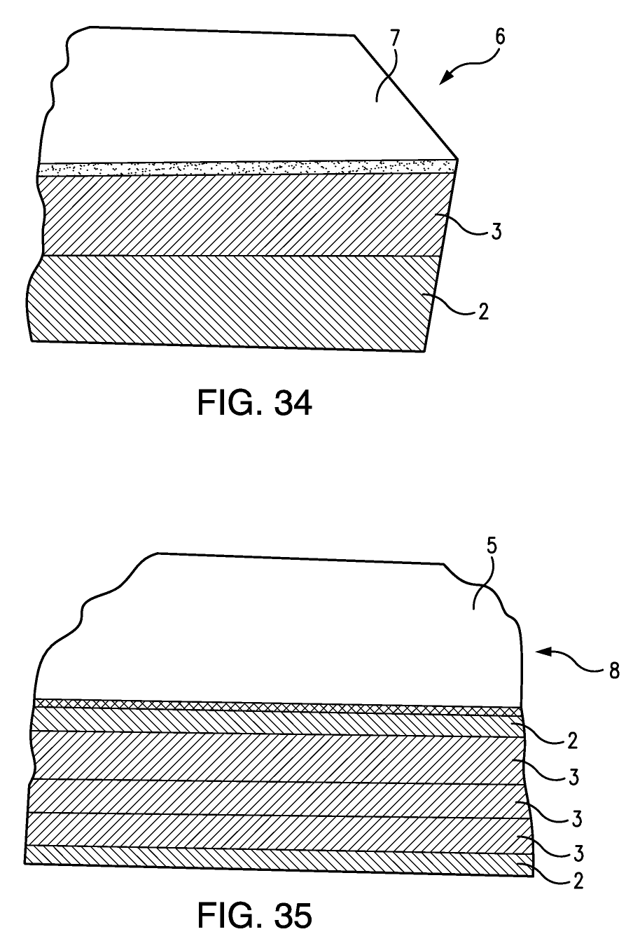

The layered insulation material 6 may also include at least one layer of graphite paint 7 (see FIG. 34). The graphite paint layer 7 may be applied to further reduce dusting and outgassing or to serve as a heat reflective surface. The rigid 3 and flexible layers 2 and the at least one graphite paint layer 7, in combination with or in place of at least one graphite foil layer, may be assembled in any variety of alternating relationships. FIG. 34 illustrates one example of the layered insulation material formed from rigid 2, flexible 3, and graphite paint 7 layers. In another example, the layers are arranged in a graphite paint-rigid-flexible-graphite foil-flexible-flexible-rigid configuration. In yet another example, the layers can be arranged in a graphite paint-flexible-rigid-flexible-rigid-flexible configuration.

The CFC layer may also be included, along with the rigid and flexible layers and the at least one graphite paint layer, in combination with or in place of at least one graphite foil layer. In one example, the layers can be arranged in a graphite paint-rigid-flexible-graphite foil-flexible-flexible-rigid-CFC configuration. In another example, the layers can be arranged in a graphite paint-flexible-rigid-flexible-rigid-flexible-CFC configuration.

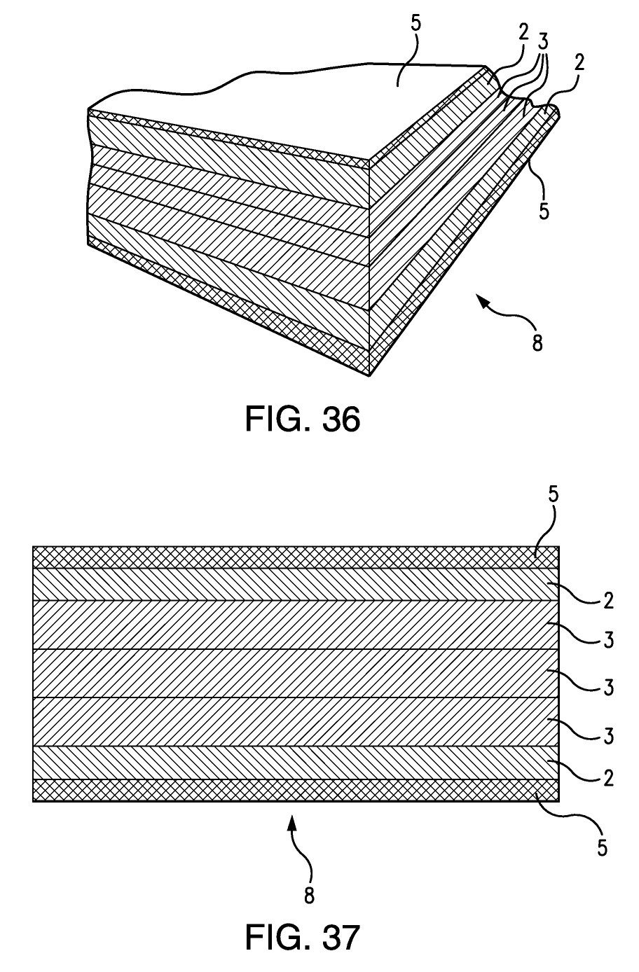

The layered insulation material 8 can be formed as illustrated in FIGS. 35, 36, and 37. The layers are arranged in a graphite foil 5-rigid 2-flexible 3-flexible 3-flexible 3-rigid 2-graphite foil 5 configuration. Each graphite foil layer 5 is approximately 0.5 mm thick, each rigid layer 2 is approximately 10 mm thick, and each flexible layer 3 is approximately 25 mm thick.

The layered materials can be purified using temperature, temperature and vacuum, and/or temperature and halogen gases. After the layers are assembled, the layered insulation material may be machined into a variety of configurations, including, but not limited to, rectangular, square, hexagonal, cylindrical, conical, and the like. The materials can be machined to complex shapes that substantially conform to furnace or other equipment shapes.

By combining the insulative properties of the flexible material with the enhanced structural strength and stiffness of rigid board, the present invention provides thermal insulation in areas such as in the production of semiconductor materials.

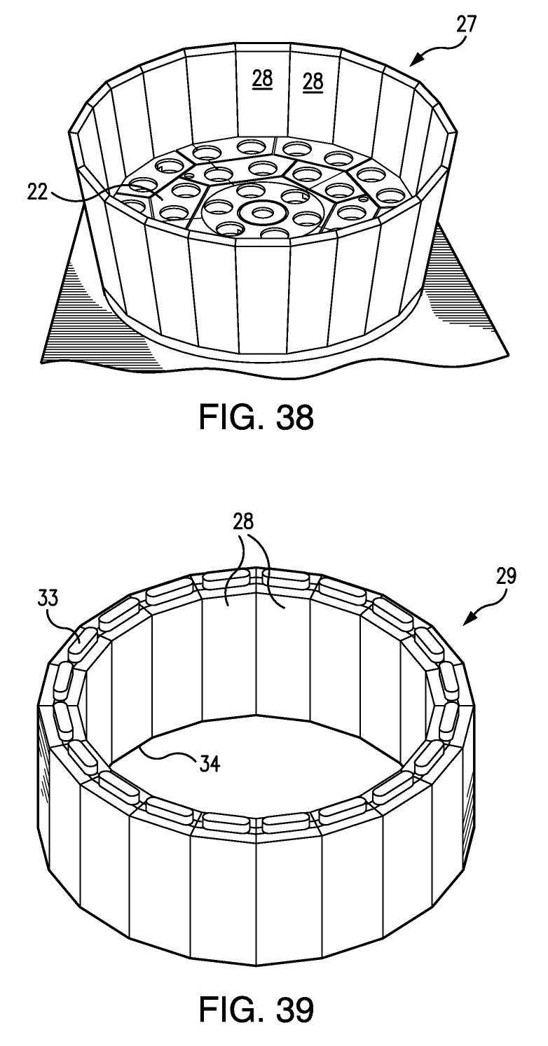

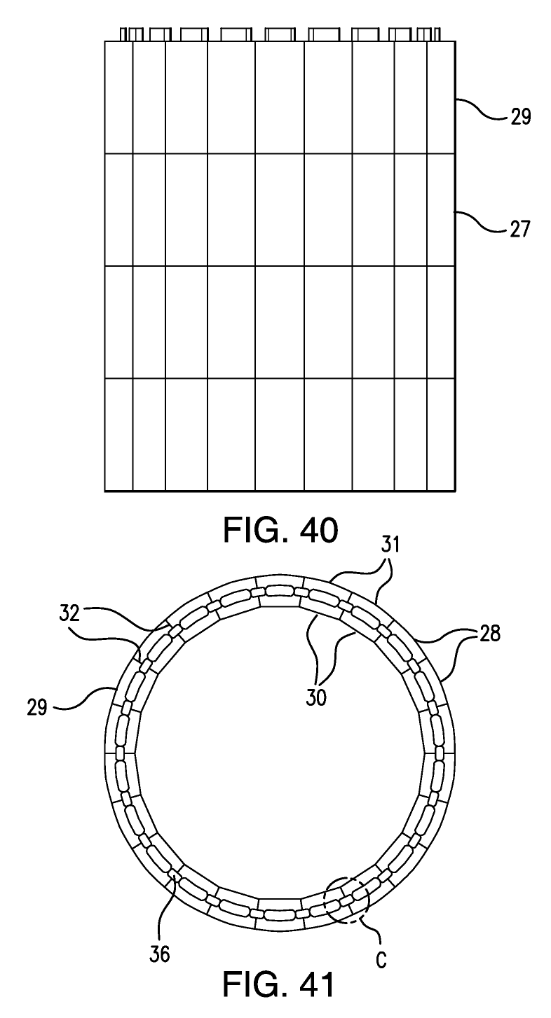

In the present invention as shown in FIGS. 38 to 40, an insulation liner 27 can be formed from an assembly of a plurality of units 28 joined together by a suitable interlocking mechanism. As shown in the FIGS. 39 and 40, the insulation liner 27 can be built up from ring shaped sub-assemblies 29 assembled from individual interlocking units 28. The number of ring shaped sub-assemblies 29 determines the height of the insulation liner 27.

There is no restriction to the extent to which the insulation liner is broken down into individual units but the number of units used to create the insulation liner should not be too excessive to jeopardise the structural strength and integrity of the insulation liner in practical use. An effective unit for use in the present invention is of a rectangular or square shape.

The present invention also relates to an apparatus for performing a thermally controlled gas phase chemical process using or producing gases. The apparatus can comprise a chamber and an insulation liner housed within the chamber and comprising carbon based materials, wherein the insulation liner comprises an assembly of a plurality of interlocked units.

Contrary to the previous belief that integral bodies are required to form the insulation liner and/or the base plate, and contrary to the expectation that reactant gases would migrate between the joints of adjoining interlocking units, with the present invention, interlocked units can provide adequate gas and heat retention together with sufficient structural strength and stiffness to the assembled insulation liner to maintain its shape at the high reaction temperatures.

The joints formed by interlocking successive units define a tortuous path between the interior and exterior surface of the insulation liner and thereby inhibit heat losses from the liner and the escape of the gases. Currently in the art, if any one area of the insulation liner degrades, the entire liner body needs to be replaced resulting in increased costs. This is particularly prevalent due to the corrosive nature of the gasses and their by-products such as chlorosilanes and hydrogen chloride gas. In the present invention, on the other hand, any one area of the insulation liner can be repaired by replacing one or more of the individual insulation units.

Breaking down the insulation liner into individual units or even sub-units reduces the problems associated with handling, transport or storage of the liner. The sub-units can be substantially flat allowing each unit to be easily fabricated from simple forming techniques such as isostatic pressing or iso-pressing techniques and requiring little machining operations compared to curved or arcuate type bodies. Moreover, the properties of the units and/or sub-units can be easily enhanced by the addition of one or more layers of other materials having superior structural or insulation properties.

Optionally, at least one side of each of the unit or sub-unit may be formed with an interlocking feature so as to co-operate with a complementary interlocking feature of an adjacent unit or sub-unit. Optionally, all sides of the sub-unit may be formed with interlocking features.

Optionally, the interlocking feature comprises a tongue-like projection receivable in a complementary groove or recess of an adjacent unit. The tongue and groove assembly at the joints defines a tortuous path between the interior and exterior of the assembled liner for the reaction gasses. Such a tortuous path at the joints avoids the formation of straight through slots at the joints between adjacent abutting units or sub-units where the gasses or heat can easily leak through causing undesirable losses.

Alternatively, the units may comprise complementary grooves or recesses which in adjacent units co-operate to form a channel to receive a key to interlock the adjacent units together. The units may be snap-fitted together to prevent the units from disassembling.

In addition to providing insulating properties, the units need to withstand the corrosive nature of the gases during the production of semi-conductor materials. Therefore, at least one unit comprises carbon, such as carbon fibre. By combining the insulative properties of felt insulation with the enhanced structural strength and stiffness of the rigid board, the units can possess the properties of the rigid board insulating material as described above.

The insulation liner may provide insulation in both the CVD Reactor and the Thermal Convertor.

The apparatus may be a reactor for chemical vapour deposition of a semiconductor material onto a heating source by the thermal decomposition of a gaseous precursor compound of the semiconductor material.

If the semiconductor material is silicon the gaseous precursor compound may comprise a silane gas, for example monosilane, disilane and/or mixtures thereof. The gaseous precursor may comprise a halosilane gas, for example trichlorosilane.

The apparatus may be a convertor for the production of a gaseous precursor compound of a semiconductor material for use in a reactor.

Any interlocking mechanism commonly known in the art that defines a tortuous path at the joint between the interior and external faces of the insulation liner for inhibiting heat loss and escape of the exhaust gases from the conversion chamber is permissible. This not only ensures that each unit is interlocked within a ring as shown in FIG. 39 but the individual rings can be joined together to form the cylindrical body as shown in FIG. 40. For example, in a typical Thermal Convertor, the insulation liner can be assembled from four rings, each ring formed from twenty interlocked units. Thus, a total of eighty units make up the cylindrical body of the insulation liner. Alternatively, each unit can be formed into rings and the insulation body can be formed by assembling the ring shaped units together. Although, the insulation body is shown as a cylindrical body, the present invention is not restricted to a cylindrical shaped body but any other shaped body that provides effective insulation around the conversion chamber, e.g. a tubular body of elliptical, angular, or any required cross section.

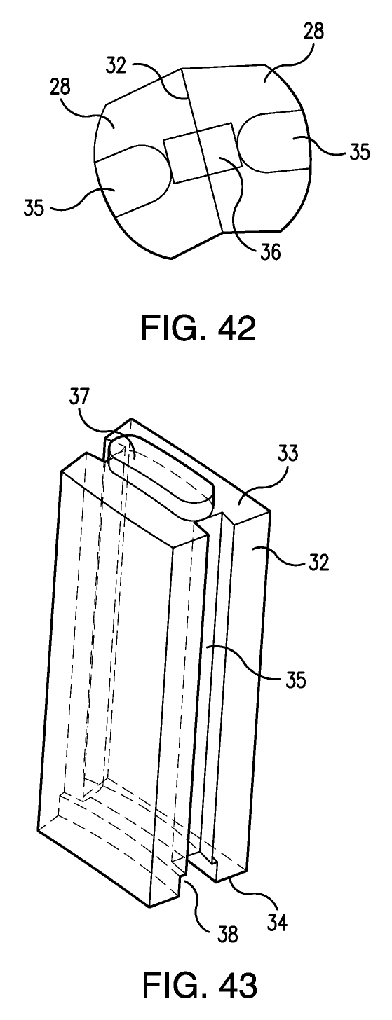

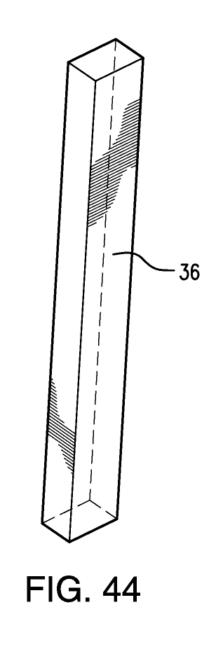

As discussed above, the interlocking feature at the joints between successive units can define a tortuous path between the interior and exterior face of the insulation liner to inhibit heat loss and the containment of the exhaust gases. Examples of interlocking features include, but not limited to, a tongue and groove mechanism or dovetail mechanism. The units can be snap-fitted together to provide a secure joint and to prevent them from disassembling. In the present invention as shown in FIGS. 39 and 41, each unit is rectangular in shape having an inner wall 30 exposed to the reaction chamber and an outer wall 31 facing away from the conversion chamber, side walls 32 which abut with adjacent units in a ring and a top 33 and bottom wall 34. The height and width of each unit may vary depending upon the size and the number of units forming the insulation liner. The insulation liner shown in FIG. 40 can be formed from an assembly of four rings, each ring formed from twenty interlocked units. For the purpose of providing thermal insulation in a Thermal Convertor, the height and width of each unit may be 20.9 inches (53.1 cm) and 9.85 inches (25 cm) respectively. Each side wall 32 of the unit may be angled such that when adjacent units butt up together they assemble into a ring as shown in FIGS. 10 and 11. Each side wall comprises a recess or groove 35 extending along the unit 28 which co-operates with a complementary groove or recess on an adjacent unit to form a channel to receive a key to interlock the adjacent units together. FIGS. 41 and 42 show an example of the joint between two abutting successive units 28. The grooves or recesses 35 of adjacent units align to form a channel or key way to receiving a key or pin 36 (see FIG. 44) in order to lock the units together. Not only does this type of interlocking mechanism lock adjacent units in a ring, but offers a tortuous path between the interior and exterior face of the insulation liner for inhibiting heat loss. Alternatively, the use of a tongue and groove mechanism or dovetail mechanism which snap-fit together does away with the use of a key.

In addition to the interlocking features formed at the side walls, the top 33 and bottom 34 wall of each unit can also be formed with an interlocking mechanism. As shown in FIG. 43, the top 33 and bottom 24 wall of each unit comprise respectively a projection 37 and a complementary groove 38 which respectively co-operate with a recess and projection from neighbouring units above and below the unit. By having interlocking features on all four sides of each unit as shown in FIG. 43, not only allows either side of the each unit to cooperate with neighbouring units laterally disposed at either side of the unit but the top and bottom wall of the unit can also co-operate with neighbouring units disposed above and below the unit. In use, each unit is interlocked within a ring of the insulation liner and the height of the insulation liner can be increased by successively increasing the number of rings to form a cylindrical body as shown in FIG. 40.

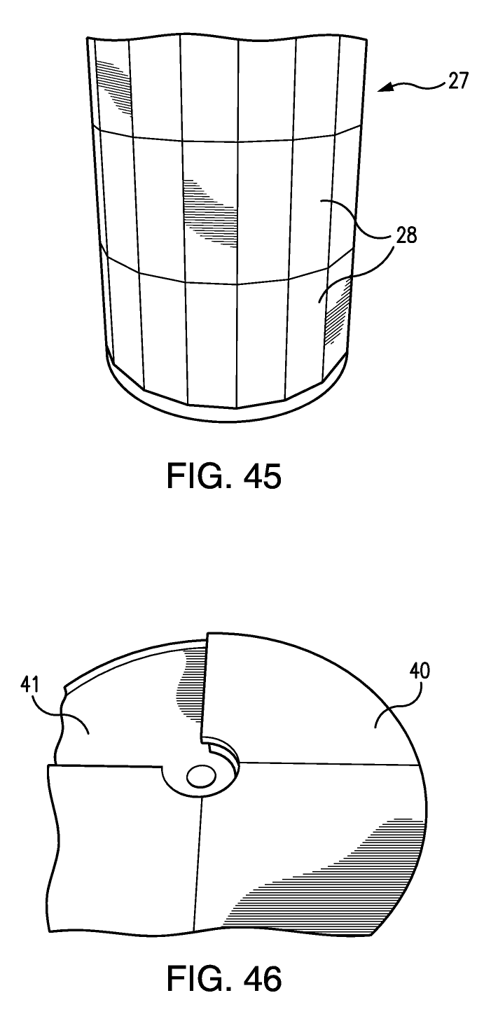

The front (inner) 30 and rear (outer) 31 walls of each unit can be flat. In comparison to curved or arcuate type faces (see FIG. 41), flat faces are easier to form requiring little machining operations. Examples of forming techniques include but not limited to pressing such as iso-static pressing and iso-pressing or casting. The recess and projections forming the interlocking features can be machined into the unit or formed during the forming operation. If the front and rear facing walls are flat, the ring will have a polygonal configuration. To more closely approximate a cylindrical form it is preferred that the rings are formed from 10 or more, preferably 20 more units. FIG. 45, shows a perspective view of the insulation liner 27 fabricated from an assembly of a plurality of interlocked units 28, whereby the front (inner) 30 and rear (outer) walls of each unit are flat, the cross-section of which having a polygonal configuration.

In addition to the insulation liner being formed from an assembly of separate discrete interlocking units discussed above, the base plate 22 (FIG. 38) and lid 40 (FIG. 46) can also be formed from an assembly of interlocking units. A similar interlocking feature as discussed for the insulation liner can be used for joining together the units in the base plate so as to provide a tortuous path between the top face and bottom face of the base plate to inhibit heat loss and the containment of the exhaust gases. To provide thermal insulation to the top cover, an insulating outer lid can form part of the top cover. The top cover as shown in FIG. 46, is formed from two plates, a graphite plate 41 which cooperate with the insulation liner to house the reactant gases during the conversion process and an outer lid 40 to provide thermal insulation during the conversion process. As with the base plate 22, the lid 40 can be formed from an assembly of a plurality of interlocked units.

To provide sufficient rigidity, stiffness and structural strength to the assembled insulation liner each unit can comprise the layered rigid-flexible insulation hybrid material as described above. The form, type and arrangement of the layers are not restricted to the insulation liner but can also apply to the fabrication and make-up of the units making up the base plate. Moreover, the arrangement of the layers in the laminate is not restricted to what is described above and other arrangements of the layers are permissible in order to provide the unit with sufficient structural strength and insulation properties. Equally, there is no restriction to the arrangement of the layer type and even the number of layers in a laminate forming the unit. For example, each unit may be formed from a laminate consisting of rigid and/or flexible and/or CFC layers. A graphite foil layer may be added to improve its sealing properties. The combination of the layers makes use of the properties of each material type which in turn enhances the properties of the unit for use as insulation in the production of semiconductor material, particularly silicon.

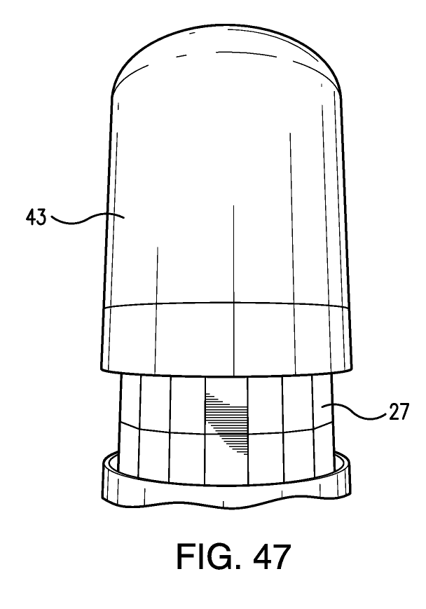

Once assembled, the insulation liner 27 can be housed in an outer steel chamber 43 (see FIG. 47) to form an air tight seal and then purged with the precursor gases for the CVD reaction process.

Although the present invention has been specifically described with reference to the Thermal Convertor for the conversion of the exhaust gases from the CVD reaction process to a gaseous precursor compound of the semiconductor material, the present invention is equally applicable to provide insulation and the base plate in a CVD Reactor. In the case of the CVD Reactor, the insulation liner cooperates with the base plate to form a reaction chamber for the reaction of the gaseous precursor compound of the semiconductor material to a semiconductor which is deposited in the CVD Reactor.

The present invention includes the following aspects/embodiments/features in any order and/or in any combination:

1. The present invention relates to a carbon-based containment system for a reactor comprising:

a) an insulation segment that comprises at least one insulation layer; and

b) a shield segment that comprises at least one shield layer,

wherein said at least one insulation layer comprises a carbon fiber rigid board, a carbon fiber rigidized felt, a carbon fiber flexible felt, a flexible graphite felt, a rigid-flexible hybrid board, a carbon foam sheet, a carbon aerogel sheet, or any combination thereof, and

wherein said at least one shield layer comprises a graphite plate, a carbon fiber composite, a carbon fiber rigid board, a carbon fiber rigidized felt, a rigid-flexible hybrid board, or a combination thereof.

2. The carbon-based containment system of any preceding or following embodiment/feature/aspect, wherein said insulation segment further comprises a secondary material that comprises vapor barrier paint, graphite foil, carbon fiber composite, vapor barrier coating other than paint, or any combination thereof.
3. The carbon-based containment system of any preceding or following embodiment/feature/aspect, wherein said secondary material is present on at least one side of said at least one insulation layer.
4. The carbon-based containment system of any preceding or following embodiment/feature/aspect, wherein said secondary material at least partially encapsulates said insulation segment.
5. The carbon-based containment system of any preceding or following embodiment/feature/aspect, wherein said secondary material fully encapsulates said insulation segment.
6. The carbon-based containment system of any preceding or following embodiment/feature/aspect, wherein said vapor barrier coating comprises glassy carbon, pyrolytic carbon, pyrolytic graphite, carbon, graphite, diamond, silicon carbide, tungsten carbide, tantalum carbide, or any combination or mixture thereof.
7. The carbon-based containment system of any preceding or following embodiment/feature/aspect, wherein said insulation segment comprises a plurality of insulation panels.
8. The carbon-based containment system of any preceding or following embodiment/feature/aspect, wherein said insulation segment comprises a plurality of insulation panels that interlock together to form a wall or section thereof.
9. The carbon-based containment system of any preceding or following embodiment/feature/aspect, further comprising connectors that connect said plurality of said insulation panels together.
10. The carbon-based containment system of any preceding or following embodiment/feature/aspect, wherein each connector of said connectors connects with a corner of each of two to four of said insulation panels.
11. The carbon-based containment system of any preceding or following embodiment/feature/aspect, wherein said at least one insulation layer comprises at least one carbon fiber rigid board or at least one carbon rigidized felt having a carbon fiber to resin weight ratio of 1 part carbon fiber:0.02 part carbonized resin to 1 part carbon fiber:3 parts carbonized resin.
12. The carbon-based containment system of any preceding or following embodiment/feature/aspect, wherein said shield segment has a thickness of from about 3 mm to about 70 mm.
13. The carbon-based containment system of any preceding or following embodiment/feature/aspect, wherein said shield segment comprises 1 to 25 shield layers, that are the same or different from each other.
14. The carbon-based containment system of any preceding or following embodiment/feature/aspect, wherein said at least one shield layer has a thickness of from about 3 mm to about 70 mm.
15. The carbon-based containment system of any preceding or following embodiment/feature/aspect, wherein said insulation segment has a thickness of from about 10 mm to about 250 mm.
16. The carbon-based containment system of any preceding or following embodiment/feature/aspect, wherein said insulation segment comprises from one insulation layer to 25 insulation layers that are the same or different from each other.
17. The carbon-based containment system of any preceding or following embodiment/feature/aspect, wherein said at least one insulation layer has a thickness from 10 mm to about 250 mm.
18. The carbon-based containment system of any preceding or following embodiment/feature/aspect, wherein said graphite foil is present and has a thickness of from about 0.15 mm to about 15 mm.
19. The carbon-based containment system of any preceding or following embodiment/feature/aspect, wherein said carbon fiber composite is present and has a thickness of from about 0.1 mm to about 50 mm.
20. The carbon-based containment system of any preceding or following embodiment/feature/aspect, wherein said vapor barrier paint is present and has a thickness of from about 0.05 mm to about 5 mm.
21. The carbon-based containment system of any preceding or following embodiment/feature/aspect, wherein said vapor barrier coating is present and has a thickness of from 0.005 mm to about 5 mm.
22. The carbon-based containment system of any preceding or following embodiment/feature/aspect, wherein said insulation segment has at least one of the following properties:

a) a thermal conductivity of less than 2.5 W/m/K at 1,600° C. when measured in one atmosphere of argon by laser flash method (ASTM E1461);

b) a flexural strength of least 10 psi as measured using four point loading (ASTM C651);

c) a coefficient of thermal expansion of less than 10×10⁻⁶ mm/(mm ° C.) as measured using a dual push-rod dilotometer (ASTM E228); and/or

d) less than 500 ppm oxygen, less than 20 ppm sodium, less than 20 ppm calcium, less than 20 ppm iron, less than 20 ppm vanadium, less than 20 ppm titanium, less than 20 ppm zirconium, less than 20 ppm tungsten, less than 5 ppm boron, less than 5 ppm phosphorus, or less than 50 ppm sulfur, or any combinations thereof.

23. The carbon-based containment system of any preceding or following embodiment/feature/aspect, wherein each of said properties are present.
24. The carbon-based containment system of any preceding or following embodiment/feature/aspect, wherein at least two of said properties are present.
25. The carbon-based containment system of any preceding or following embodiment/feature/aspect, wherein said at least one shield layer comprises said graphite plate.
26. The carbon-based containment system of any preceding or following embodiment/feature/aspect, wherein said graphite plate has at least one of the following properties:

a) an apparent density of at least 1.7 g/cm³;

b) a flexural strength of at least 8,500 psi as measured using four point loading (ASTM C651);

c) a compressive strength of at least 13,500 psi (ASTM C695);

d) a coefficient of thermal expansion of 5×10⁻⁶ mm/(mm ° C.) as measured using a dual push-rod dilotometer (ASTM E228);

e) a Shore hardness of at least 50;

f) a porosity of 15% or less; and/or

g) a purity of less than 20 ppm sodium, less than 20 ppm calcium, less than 20 ppm iron, less than 20 ppm vanadium, less than 20 ppm titanium, less than 20 ppm zirconium, less than 20 ppm tungsten, less than 5 ppm boron, less than 5 ppm phosphorus, or less than 50 ppm sulfur, or any combination thereof.

27. The carbon-based containment system of any preceding or following embodiment/feature/aspect, wherein all of said properties are present.
28. The carbon-based containment system of any preceding or following embodiment/feature/aspect, wherein at least two of said properties are present.
29. The carbon-based containment system of any preceding or following embodiment/feature/aspect, wherein said insulation segment comprises a wall that encircles said shield segment that comprises a wall.
30. The carbon-based containment system of any preceding or following embodiment/feature/aspect, wherein said insulation segment is in contact with said shield segment.
31. The carbon-based containment system of any preceding or following embodiment/feature/aspect, wherein said insulation segment is a wall that is cylindrical or polygonal and said shield segment is a wall that is cylindrical or polygonal.
32. The carbon-based containment system of any preceding or following embodiment/feature/aspect, wherein said insulation segment is a wall and said shield segment is a wall, where both encircle a heater or system of heaters of said reactor.
33. The carbon-based containment system of any preceding or following embodiment/feature/aspect, wherein said insulation segment and said shield segment are walls that are adjacent to each other such that a gap no greater than 15 cm exists between said insulation segment and said shield segment.
34. The carbon-based containment system of any preceding or following embodiment/feature/aspect, wherein said insulation segment comprises a plurality of insulation panels that are interlocked together to form a wall that is cylindrical or polygonal shape, and wherein said shield segment comprises a plurality of shield panels that are interlocked together to form a wall that is a cylindrical or polygonal shape.
35. The carbon-based containment system of any preceding or following embodiment/feature/aspect, wherein said insulation panels are interlocked together by a plurality of connectors and said plurality of connectors further connect said plurality of shield panels together.
36. The carbon-based containment system of any preceding or following embodiment/feature/aspect, further comprising a divider segment that comprises at least one divider layer.
37. The carbon-based containment system of any preceding or following embodiment/feature/aspect, wherein said at least one divider layer comprises a graphite plate, a carbon fiber composite, a carbon fiber rigid board, a carbon fiber rigidized felt, a rigid-flexible hybrid board, or a combination thereof.
38. The carbon-based containment system of any preceding or following embodiment/feature/aspect, wherein said at least one divider layer comprises a graphite plate.
39. The carbon-based containment system of any preceding or following embodiment/feature/aspect, wherein said divider segment comprises a plurality of divider panels that form at least one wall or interconnecting walls.
40. The carbon-based containment system of any preceding or following embodiment/feature/aspect, wherein said divider segment comprises a plurality of divider panels that interlock together to form a wall or a series of walls.
41. The carbon-based containment system of any preceding or following embodiment/feature/aspect, further comprising connectors that connect said plurality of said divider segments together.
42. The carbon-based containment system of any preceding or following embodiment/feature/aspect, wherein each connector connects with a corner of each of three of said divider panels.
43. The carbon-based containment system of any preceding or following embodiment/feature/aspect, wherein said divider panel that comprises a graphite plate has at least one of the following properties:

a) an apparent density of at least 1.7 g/cm³;

b) a flexural strength of at least 8,500 psi as measured using four point loading (ASTM C651);

c) a compressive strength of at least 13,500 psi (ASTM C695);

d) a coefficient of thermal expansion of 5×10⁻⁶ mm/(mm ° C.) as measured using a dual push-rod dilotometer (ASTM E228);

e) a Shore hardness of at least 50;

f) a porosity of 15% or less; and/or

g) a purity of less than 20 ppm sodium, less than 20 ppm calcium, less than 20 ppm iron, less than 20 ppm vanadium, less than 20 ppm titanium, less than 20 ppm zirconium, less than 20 ppm tungsten, less than 5 ppm boron, less than 5 ppm phosphorus, or less than 50 ppm sulfur, or any combination thereof.

44. The carbon-based containment system of any preceding or following embodiment/feature/aspect, wherein said divider panels for a wall or a series of interconnecting walls that section off various parts of a reactor and are contained within said insulation segment that forms a polygonal wall and/or said shield segment that form a polygonal wall.
45. A carbon-based containment system for a reactor comprising:

a) an insulation segment that comprises at least one insulation layer; and/or

b) a shield segment that comprises at least one shield layer,

wherein said at least one insulation layer comprises a carbonaceous material or carbon-based material, such as a carbon fiber rigid board, a carbon fiber rigidized felt, a carbon fiber flexible felt, a flexible graphite felt, a rigid-flexible hybrid board, a carbon foam sheet, a carbon aerogel sheet, or any combination thereof, and

wherein said at least one shield layer comprises a carbonaceous material or carbon-based materials, such as a graphite plate, a carbon fiber composite, a carbon fiber rigid board, a carbon fiber rigidized felt, a rigid-flexible hybrid board, or a combination thereof.

46. The carbon-based containment system of any preceding or following embodiment/feature/aspect, wherein said insulation segment is present and with the proviso that said insulation layer does not include a rigid-flexible hybrid board.
47. The carbon-based containment system of any preceding or following embodiment/feature/aspect, wherein said insulation segment is present and said at least one insulation layer comprises:

a) an insulation segment that comprises at least one insulation layer; or

b) a shield segment that comprises at least one shield layer,

wherein said at least one insulation layer comprises a carbon fiber rigid board, a carbon fiber rigidized felt, a carbon fiber flexible felt, a flexible graphite felt, a carbon foam sheet, a carbon aerogel sheet, or any combination thereof, and

wherein said at least one shield layer comprises a graphite plate, a carbon fiber composite, a carbon fiber rigid board, a carbon fiber rigidized felt, a rigid-flexible hybrid board, or a combination thereof.

48. A panel connector for connecting two or more panels together, the panel connector comprising:

a first pair of opposing walls each comprising a planar inner surface, the inner surfaces of the first pair of opposing walls being oriented parallel to one another;

a bottom wall comprising a first planar surface that intersects with each of the planar inner surfaces of the first pair of opposing walls such that the first pair of opposing walls and the bottom wall together form a first groove having planar inner side-walls normal to a planar bottom surface;

a second pair of opposing walls each comprising a planar inner surface, the inner surfaces of the second pair of opposing walls being oriented parallel to one another and intersecting the first planar surface of the bottom wall such that the second pair of opposing walls and the bottom wall together form a second groove having planar inner side-walls normal to a planar bottom surface;

wherein the first groove intersects the second groove at an intersection of grooves, the bottom surface of the first groove is co-planar with the bottom surface of the second groove, neither of the opposing walls of the first pair of opposing walls is co-planar with either of the opposing walls of the second pair of opposing walls, and the first pair of opposing walls, the second pair of opposing walls, and the bottom wall all comprise a carbon-based material.

49. The panel connector of any preceding or following embodiment/feature/aspect, wherein the first groove and the second groove are angled with respect to one another and the intersection of grooves comprises a corner.
50. The panel connector of any preceding or following embodiment/feature/aspect, wherein the intersection of grooves comprises a curved surface.
51. The panel connector of any preceding or following embodiment/feature/aspect, wherein the first pair of opposing walls and the bottom wall together have a [symbol] -shaped cross-section when taken perpendicular to the first groove, and the second pair of opposing walls and the bottom wall together have a [symbol] -shaped cross-section when taken perpendicular to the second groove.
52. The panel connector of any preceding or following embodiment/feature/aspect, wherein the bottom wall has a second planar surface opposite the first planar surface and the panel connector further comprises:

a third pair of opposing walls each comprising a planar inner surface and being oriented parallel to one another, the planar inner surfaces of the third pair of opposing walls intersecting the second planar surface of the bottom wall to form a third groove that faces away from the first groove; and

a fourth pair of opposing walls each comprising a planar inner surface and being oriented parallel to one another, the planar inner surfaces of the fourth pair of opposing walls intersecting the second planar surface of the bottom wall to form a fourth groove that faces away from the second groove;

wherein the third groove intersects the fourth groove at a second intersection of grooves, the bottom surface of the third groove is co-planar with the bottom surface of the fourth groove, neither of the opposing walls of the third pair of opposing walls is co-planar with either of the opposing walls of the fourth pair of opposing walls, and the third pair of opposing walls and the fourth pair of opposing walls comprise a carbon-based material.

53. The panel connector of any preceding or following embodiment/feature/aspect, wherein the first pair of opposing walls, the bottom wall, and the third pair of opposing walls together have an H-shaped cross-section when taken perpendicular to the first and third grooves, and the second pair of opposing walls, the bottom wall, and the fourth pair of opposing walls together have an H-shaped cross-section when taken perpendicular to the second and fourth grooves.
54. The carbon-based containment system of any preceding or following embodiment/feature/aspect, wherein an insulation segment and/or shield segment and/or divider segment and/or connectors are present, and wherein said insulation segment and/or shield segment and/or divider segment and/or connectors further comprise at least one secondary material.
55. A rigid-flexible hybrid insulation material comprising:
a. a first layer comprising a rigid insulation material; and
b. a second layer comprising a flexible insulation material, wherein the first layer and second layer comprises carbon based material.
   56. A rigid-flexible hybrid insulation material of any preceding or following embodiment/feature/aspect, wherein the thickness of the second layer is at least 0.25 inch (0.6 cm).
   57. The rigid-flexible hybrid insulation material of any preceding or following embodiment/feature/aspect, further comprising at least one additional layer of the rigid insulation material.
   58. The rigid-flexible hybrid insulation material of any preceding or following embodiment/feature/aspect, further comprising at least one additional layer of the flexible insulation material, wherein the combined thickness of the flexible insulation material and the second layer is at least 0.25 inch (0.6 cm).
   59. The rigid-flexible hybrid insulation material of any preceding or following embodiment/feature/aspect, further comprising at least one layer of graphite foil.
   60. The rigid-flexible hybrid insulation material of any preceding or following embodiment/feature/aspect, further comprising at least one layer of CFC.
   61. The rigid-flexible hybrid insulation material of any preceding or following embodiment/feature/aspect, further comprising at least one layer of graphite paint.
   62. The rigid-flexible hybrid insulation material of any preceding or following embodiment/feature/aspect, wherein the thickness of the rigid-flexible hybrid insulation material is at least 0.25 inches (0.6 cm).
   63. The rigid-flexible insulation material of any preceding or following embodiment/feature/aspect, wherein the first and second layers comprises carbon fiber.
   64. The rigid-flexible hybrid insulation material of any preceding or following embodiment/feature/aspect, wherein the first and second layers are formed from different carbon fiber precursors.
   65. A method of forming a rigid-flexible hybrid insulation material as defined in any preceding or following embodiment/feature/aspect, comprising the step of:
a. adhering the first layer to the second layer using a bonding agent to form a laminated material,
b. heat treating the laminated material in an inert atmosphere.
   66. The method in any preceding or following embodiment/feature/aspect, further comprising the step of heating treating the laminated material to cure the bonding agent.
   67. The method in any preceding or following embodiment/feature/aspect, further comprising the step of holding the first and second layers together under pressure of at least 0.03 bar during the heat treatment process to cure the bonding agent.
   68. The method in any preceding or following embodiment/feature/aspect, wherein the bonding agent comprises a carbon precursor.
   69. The method in any preceding or following embodiment/feature/aspect, wherein the bonding agent comprises a mixture of phenolic resin and corn syrup.
   70. A method in any preceding or following embodiment/feature/aspect, wherein the laminated material is heat treated in an inert atmosphere to carbonise the bonding agent.
   71. Apparatus for performing a thermally controlled gas phase chemical process using or producing gases, the apparatus comprising a chamber and an insulation liner housed within the chamber and comprising carbon based materials, wherein the insulation liner comprises an assembly of a plurality of interlocked units.
   72. Apparatus in any preceding or following embodiment/feature/aspect, further comprising a base and/or a lid for cooperating with the insulation liner housed within the chamber, the base and/or lid comprises carbon based materials, wherein the base and/or the lid comprises an assembly of a plurality of interlocked units.
   73. Apparatus in any preceding or following embodiment/feature/aspect, wherein the insulating liner is formed from two or more ring assemblies of interlocked units stacked in interlocked relationship.
   74. Apparatus in any preceding or following embodiment/feature/aspect, wherein the interlocked units are substantially flat.
   75. Apparatus in any preceding or following embodiment/feature/aspect, wherein at least two sides of at least one unit are formed with an interlocking feature so as to co-operate with a complementary interlocking feature of an adjacent unit.
   76. Apparatus in any preceding or following embodiment/feature/aspect, wherein all sides of at least one unit are formed with interlocking features.
   77. Apparatus in any preceding or following embodiment/feature/aspect, wherein the interlocking feature on at least one side comprises a tongue-like projection receivable in a complementary groove or recess in an adjacent unit.
   78. Apparatus in any preceding or following embodiment/feature/aspect, wherein the interlocking feature on at least one side of a unit comprises a groove or recess which co-operates with a complementary groove or recess on an adjacent unit to form a channel to receive a key to interlock the adjacent units together.
   79. Apparatus in any preceding or following embodiment/feature/aspect, wherein at least one unit comprises carbon fibre.
   80. Apparatus in any preceding or following embodiment/feature/aspect, wherein said at least one unit comprises rigid-flexible board insulating material as defined in any preceding or following embodiment/feature/aspect.
   81. Apparatus in any preceding or following embodiment/feature/aspect, wherein the apparatus is a reactor for chemical vapour deposition of semiconductor material onto a heating source by the thermal decomposition of a gaseous precursor compound of the semiconductor material.
   82. Apparatus in any preceding or following embodiment/feature/aspect, wherein the apparatus is a convertor for the production of the gaseous precursor compound of the semiconductor material in the reactor defined in any preceding or following embodiment/feature/aspect.
   83. Apparatus in any preceding or following embodiment/feature/aspect, wherein the apparatus is for performing a thermally controlled gas phase chemical process using or producing corrosive gases.
   84. A unit comprising carbon based materials and provided with interlocking features and adapted for use as an interlocked unit in the apparatus of any preceding or following embodiment/feature/aspect.
   85. A unit comprising rigid-flexible hybrid insulation material as defined in any preceding or following embodiment/feature/aspect, and provided with interlocking features and adapted for use as an interlocked unit in the apparatus of any preceding or following embodiment/feature/aspect.
   86. A key adapted for use in interlocking units in the apparatus of any preceding or following embodiment/feature/aspect.
   87. A kit for manufacture of an insulating liner for use in the apparatus of any preceding or following embodiment/feature/aspect, comprising a plurality of units as in any preceding or following embodiment/feature/aspect.
   88. An insulating liner, or a base or a top plate, for use in the apparatus of any preceding or following embodiment/feature/aspect, and comprising a plurality of interlocked units.
   89. An insulating liner of any preceding or following embodiment/feature/aspect, wherein the cross-section of the insulating liner is substantially polygonal.
   90. Method of providing an insulation liner in the apparatus of any preceding or following embodiment/feature/aspect, comprising the step of interlocking a plurality of units of any preceding or following embodiment/feature/aspect.
   91. Method of providing a base and/or lid in the apparatus of any preceding or following embodiment/feature/aspect, comprising the step of interlocking a plurality of units as defined in any preceding or following embodiment/feature/aspect.

The present invention can include any combination of these various features or embodiments above and/or below as set forth in sentences and/or paragraphs. Any combination of disclosed features herein is considered part of the present invention and no limitation is intended with respect to combinable features.

The present invention will be further clarified by the following examples, which are intended to be exemplary of the present invention.

### EXAMPLES

### Example 1

A carbon-based containment system having an insulation segment, a shield segment, and a divider segment was made and had the set-up shown in FIGS. 1-28.

### Manufacture of the Shield Segment (Inner Shield)

A 300 mm (11.81 inch)×600 mm (23.62 inch)×1000 mm (39.37 inch) block of Morgan AM&T EY308 graphite was cut with a band saw into ten 25 mm (0.98 inch)×600 mm (23.62 inch)×1000 mm (39.37 inch) plates. From these plates, the five annular top and five annular bottom inner shield parts were machined using a combination of surface grinders and three-axis milling machines. Likewise, an 810 mm (31.89 inch) diameter×150 mm (5.91 inch) length cylinder of EY308 graphite was cut into two 810 mm (31.89 inch) diameter×25 mm (0.98 inch) disks. From these plates, the two disc-shaped top and bottom shield parts were machined using a combination of surface grinders and three-axis milling machines.

A 300 mm (11.81 inch)×500 mm (19.69 inch)×1000 mm (39.37 inch) block of Morgan AM&T EY308 graphite was cut with a band saw into forty plates, each 15 mm (0.59 inch)×247 mm (9.72 inch)×691 mm (27.20 inch). From these plates, the forty parts that comprise the top and bottom ring of the inner shield were machined using a combination of surface grinders and three-axis milling machines. Similarly, from a 300 mm (11.81 inch)×600 mm (23.62 inch)×1220 mm (48.03 inch) block of EY308 graphite, twenty plates 15 mm (0.59 inch)×247 mm (9.72 inch)×695 mm (27.36 inch) were cut using a band saw. These are machined using a surface grinder and a three-axis milling machine into the twenty parts that comprise the middle ring of the inner shield.

A 300 mm (11.81 inch)×500 mm (19.69 inch)×1000 mm (39.37 inch) block of Morgan AM&T EY308 graphite was cut with a band saw into eighty blocks each 39 mm (1.54 inch)×58 mm (2.28 inch)×68 mm (2.68 inch). From these forty inner shield middle connectors and forty inner shield top/bottom connectors were machined using a three-axis milling machine.

The parts that comprise the inner shield are purified in a halogen gas capable vacuum furnace.

### Manufacture of Insulation Segment (Outer Liner)

The side walls of the outer liner were manufactured from two-side graphite foil coated Morgan AM&T Solar Grade Rigid Board from sixty boards that are 25 mm (0.984 inch)×267 mm (10.522 inch)×721 mm (28.39 inch). These boards were machined using a five-axis router into the forty top/bottom insulation bricks and twenty middle insulation bricks.

The top and bottom outer insulation liner parts were manufactured from Morgan AM&T Solar Grade Rigid Board. The four annular parts of the top and four annular parts of the bottom liner were machined from boards that are 68 mm (2.691 inch)×745 mm (29.33 inch)×1172 mm (46.142 inch) using a five-axis router. The disk part of the top and bottom liner were each machined using a five-axis router from boards that were 68 mm (2.691 inch)×285 mm (11.25 inch)×285 mm (11.25 inch).

### Manufacture of Divider Segment (Inner Dividers)

A 300 mm (11.81 inch)×600 mm (23.62 inch)×1220 mm (48.03 inch) block of Morgan AM&T EY308 graphite was cut with a band saw into thirty-six 15 mm (0.59 inch)×402 mm (16.02 inch)×521 mm (20.51 inch) plates and twenty-four 15 mm (0.59 inch)×389 mm (15.31 inch)×521 mm (20.51 inch) plates. A second block of Morgan AM&T EY308 300 mm (11.81 inch)×600 mm (23.62 inch)×1220 mm (48.03 inch) was cut with a band saw into one hundred plates mm (0.59 inch)×170 mm (6.69 inch)×521 mm (20.51 inch). These plates were machined using a surface grinder and a three-axis milling machine into one hundred sixty inner divider plates.

A 300 mm (11.81 inch)×500 mm (19.69 inch)×1000 mm (39.37 inch) block of Morgan AM&T EY308 graphite was cut with a band saw into seventy-five blocks each 68 mm (2.68 inch)×68 mm (2.68 inch)×68 mm (2.68 inch). From these blocks, the thirty top/bottom connectors and the forty-five middle connectors were machined using a three-axis milling machine.

The parts that comprise the inner shield were purified in a halogen gas capable vacuum furnace.

The insulation segment was then formed into an interlocking polygonal wall along with the shield segment using connectors made from the EY308 graphite that can encircle a reactor. The connectors had the shape set forth in the Figures. The insulation panels and shield panels abutted against each other and used the same connectors to form an interlocking insulation wall and shield wall. The divider segment was also formed into a series of interlocking walls using the connectors of FIGS. 16-31, made from the EY308 graphite. The divider walls were designed to be within the polygonal insulation/shield walls.

### Example 2

A rigid insulation layer, obtained from Morgan Rigid Board, is cut to dimensions of 25 inches (63.5 cm)×25 inches (63.5 cm)×0.5 inches (1.3 cm). Morgan Rigid Board is a rigid carbon fiber insulating material and comprises 0.3-4 mm lengths of rayon derived carbon fibers intimately mixed with a phenolic resin. Two layers of flexible insulation material (Morgan AM&T VDG) having a thickness of 0.5 inch (1.3 cm) are prepared by cutting into 25 inches (63.5 cm)×25 inches (63.5 cm) sections. The bonding agent for bonding the layers of the flexible and rigid together is prepared by mixing Karo Lite corn syrup and a phenolic resin known as Georgia-Pacific 5520, in a 10:1 mass ratio. The bonding surface of the rigid and flexible layers are then coated with the bonding agent to a thickness of approximately about 0.0625 inches (0.16 cm) and the layers of insulation are brought together in an arrangement of one layer of rigid insulation, two layers of the flexible insulation and one layer of the rigid insulation. The bonding agent is cured at a temperature of 125° C. for a period of 24 hours to harden the resin and thereby, bond the layers together. During the curing of the bonding agent, the material is held continuously under a pressure of at least 0.44 psi (0.03 bar) to ensure that the layers of insulation are sufficiently bonded together. The cured flexible-rigid hybrid material is then heat treated to a temperature of 1900° C. in an inert atmosphere (nitrogen) in order to carbonise the resin and form a carbon bond between the layers of insulation. Finally, after this heat treatment process, the laminated structure may be cut to dimensions for use in insulating applications.

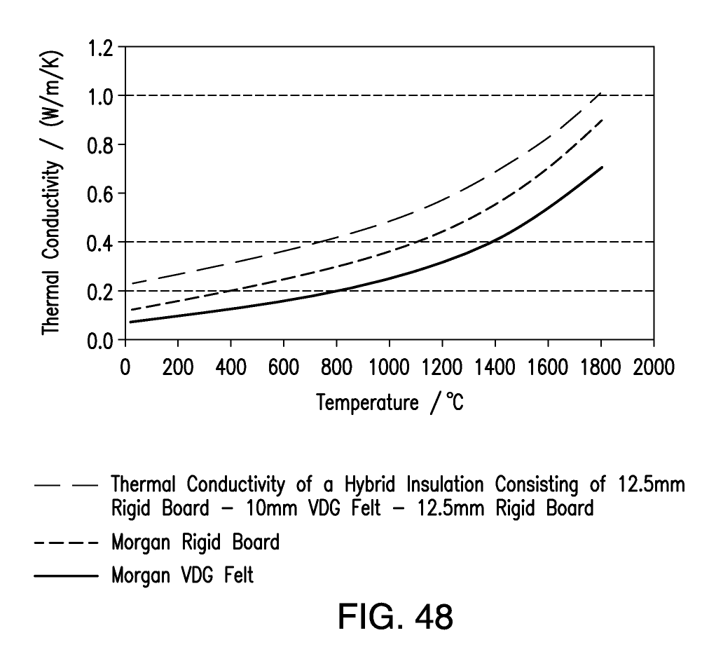

FIG. 48 shows a plot showing the thermal conductivity results of a rigid-flexible hybrid insulation material in a comparison with the thermal conductivity results from a rigid board (Morgan Rigid Board) and a flexible insulation material (Morgan AM&T VDG). It is clearly apparent from the plot shown in FIG. 48, that the thermal conductivity of the rigid-flexible hybrid insulation material lies between the thermal conductivity properties of the rigid material and the flexible material, the flexible insulation material having the least thermal conductivity and the rigid material having the greatest thermal conductivity. By combining the flexible material with the rigid material, the rigid-flexible hybrid material of the present invention benefits from the superior insulative properties of the flexible material and the structural properties of the rigid material. As one would expect from the plot, that the greater the number of layers of the flexible material or the greater its thickness, the greater the insulative effect of the rigid-flexible hybrid material would offer. Likewise, the greater the number of layers of the rigid material, the greater the structural strength of the rigid-flexible hybrid material would be. Thus, the insulative properties and the structural properties of the rigid-flexible hybrid material can be tailored to meet the requirements intended for the application by varying the number and/or the order of the flexible and rigid layers in the rigid-flexible hybrid material of the present invention.

Applicants specifically incorporate the entire contents of all cited references in this disclosure. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

1-92. (canceled)

93. A carbon-based containment system for a reactor comprising:
a) an insulation segment that comprises at least one insulation layer; and
b) a shield segment that comprises at least one shield layer,
wherein said at least one insulation layer comprises a carbon fiber rigid board, a carbon fiber rigidized felt, a carbon fiber flexible felt, a flexible graphite felt, a rigid-flexible hybrid board, a carbon foam sheet, a carbon aerogel sheet, or any combination thereof, and
wherein said at least one shield layer comprises a graphite plate, a carbon fiber composite, a carbon fiber rigid board, a carbon fiber rigidized felt, a rigid-flexible hybrid board, or a combination thereof,
wherein said insulation segment comprises a plurality of insulation panels that interlock together to form a wall or section thereof.

94. The carbon-based containment system of claim 93, wherein said insulation segment further comprises a secondary material that comprises vapor barrier paint, graphite foil, carbon fiber composite, vapor barrier coating other than paint, or any combination thereof, wherein said secondary material is present on at least one side of said at least one insulation layer.

95. The carbon-based containment system of claim 93, wherein said vapor barrier coating comprises glassy carbon, pyrolytic carbon, pyrolytic graphite, carbon, graphite, diamond, silicon carbide, tungsten carbide, tantalum carbide, or any combination or mixture thereof.

96. The carbon-based containment system of claim 93, wherein said insulation segment comprises a plurality of insulation panels, further comprising connectors that connect said plurality of said insulation panels together.

97. The carbon-based containment system of claim 93, wherein said insulation segment has at least one of the following properties:
a) a thermal conductivity of less than 2.5 W/m/K at 1,600° C. when measured in one atmosphere of argon by laser flash method (ASTM E1461);
b) a flexural strength of least 10 psi as measured using four point loading (ASTM C651);
c) a coefficient of thermal expansion of less than 10×10⁻⁶ mm/(mm ° C.) as measured using a dual push-rod dilotometer (ASTM E228); and/or
d) less than 500 ppm oxygen, less than 20 ppm sodium, less than 20 ppm calcium, less than 20 ppm iron, less than 20 ppm vanadium, less than 20 ppm titanium, less than 20 ppm zirconium, less than 20 ppm tungsten, less than 5 ppm boron, less than 5 ppm phosphorus, or less than 50 ppm sulfur, or any combinations thereof.

98. The carbon-based containment system of claim 93, wherein said at least one shield layer comprises said graphite plate, wherein said graphite plate has at least one of the following properties:
a) an apparent density of at least 1.7 g/cm³;
b) a flexural strength of at least 8,500 psi as measured using four point loading (ASTM C651);
c) a compressive strength of at least 13,500 psi (ASTM C695);
d) a coefficient of thermal expansion of 5×10⁻⁶ mm/(mm ° C.) as measured using a dual push-rod dilotometer (ASTM E228);
e) a Shore hardness of at least 50;
f) a porosity of 15% or less; and/or
g) a purity of less than 20 ppm sodium, less than 20 ppm calcium, less than 20 ppm iron, less than 20 ppm vanadium, less than 20 ppm titanium, less than 20 ppm zirconium, less than 20 ppm tungsten, less than 5 ppm boron, less than 5 ppm phosphorus, or less than 50 ppm sulfur, or any combination thereof.

99. The carbon-based containment system of claim 93, wherein said insulation segment comprises a wall that encircles said shield segment that comprises a wall.

100. The carbon-based containment system of claim 93, wherein said insulation segment and said shield segment are walls that are adjacent to each other such that a gap no greater than 15 cm exists between said insulation segment and said shield segment.

101. The carbon-based containment system of claim 93, wherein said insulation segment comprises a plurality of insulation panels that are interlocked together to form a wall that is cylindrical or polygonal shape, and wherein said shield segment comprises a plurality of shield panels that are interlocked together to form a wall that is a cylindrical or polygonal shape, wherein said insulation panels are interlocked together by a plurality of connectors and said plurality of connectors further connect said plurality of shield panels together.

102. The carbon-based containment system of claim 93, further comprising a divider segment that comprises at least one divider layer, wherein said at least one divider layer comprises a graphite plate, a carbon fiber composite, a carbon fiber rigid board, a carbon fiber rigidized felt, a rigid-flexible hybrid board, or a combination thereof.

103. The carbon-based containment system of claim 102, wherein said divider segment comprises a plurality of divider panels that interlock together to form a wall or a series of walls, and further comprising connectors that connect said plurality of said divider segments together.

104. The carbon-based containment system of claim 103, wherein said divider panel comprises a graphite plate has at least one of the following properties:
a) an apparent density of at least 1.7 g/cm³;
b) a flexural strength of at least 8,500 psi as measured using four point loading (ASTM C651);
c) a compressive strength of at least 13,500 psi (ASTM C695);
d) a coefficient of thermal expansion of 5×10⁻⁶ mm/(mm ° C.) as measured using a dual push-rod dilotometer (ASTM E228);
e) a Shore hardness of at least 50;
f) a porosity of 15% or less; and/or
g) a purity of less than 20 ppm sodium, less than 20 ppm calcium, less than 20 ppm iron, less than 20 ppm vanadium, less than 20 ppm titanium, less than 20 ppm zirconium, less than 20 ppm tungsten, less than 5 ppm boron, less than 5 ppm phosphorus, or less than 50 ppm sulfur, or any combination thereof.

105. A panel connector for connecting two or more panels together, the panel connector comprising:
a first pair of opposing walls each comprising a planar inner surface, the inner surfaces of the first pair of opposing walls being oriented parallel to one another;
a bottom wall comprising a first planar surface that intersects with each of the planar inner surfaces of the first pair of opposing walls such that the first pair of opposing walls and the bottom wall together form a first groove having planar inner side-walls normal to a planar bottom surface;
a second pair of opposing walls each comprising a planar inner surface, the inner surfaces of the second pair of opposing walls being oriented parallel to one another and intersecting the first planar surface of the bottom wall such that the second pair of opposing walls and the bottom wall together form a second groove having planar inner side-walls normal to a planar bottom surface;
wherein the first groove intersects the second groove at an intersection of grooves, the bottom surface of the first groove is co-planar with the bottom surface of the second groove, neither of the opposing walls of the first pair of opposing walls is co-planar with either of the opposing walls of the second pair of opposing walls, and the first pair of opposing walls, the second pair of opposing walls, and the bottom wall all comprise a carbon-based material.

106. The panel connector of claim 105, wherein the first groove and the second groove are angled with respect to one another and the intersection of grooves comprises a corner or a curved surface.

107. The panel connector of claim 105, wherein the first pair of opposing walls and the bottom wall together have a [symbol] -shaped cross-section when taken perpendicular to the first groove, and the second pair of opposing walls and the bottom wall together have a [symbol] -shaped cross-section when taken perpendicular to the second groove.

108. The panel connector of claim 105, wherein the bottom wall has a second planar surface opposite the first planar surface and the panel connector further comprises:
a third pair of opposing walls each comprising a planar inner surface and being oriented parallel to one another, the planar inner surfaces of the third pair of opposing walls intersecting the second planar surface of the bottom wall to form a third groove that faces away from the first groove; and
a fourth pair of opposing walls each comprising a planar inner surface and being oriented parallel to one another, the planar inner surfaces of the fourth pair of opposing walls intersecting the second planar surface of the bottom wall to form a fourth groove that faces away from the second groove;
wherein the third groove intersects the fourth groove at a second intersection of grooves, the bottom surface of the third groove is co-planar with the bottom surface of the fourth groove, neither of the opposing walls of the third pair of opposing walls is co-planar with either of the opposing walls of the fourth pair of opposing walls, and the third pair of opposing walls and the fourth pair of opposing walls comprise a carbon-based material.

109. The panel connector of claim 108, wherein the first pair of opposing walls, the bottom wall, and the third pair of opposing walls together have an H-shaped cross-section when taken perpendicular to the first and third grooves, and the second pair of opposing walls, the bottom wall, and the fourth pair of opposing walls together have an H-shaped cross-section when taken perpendicular to the second and fourth grooves.

110. Apparatus for performing a thermally controlled gas phase chemical process using or producing gases, the apparatus comprising a chamber and an insulation liner housed within the chamber and comprising carbon based materials, wherein the insulation liner comprises an assembly of a plurality of interlocked units,
wherein at least two sides of at least one unit are formed with an interlocking feature so as to co-operate with a complementary interlocking feature of an adjacent unit, and
wherein the interlocking feature on at least one side of a unit comprises a groove or recess which co-operates with a complementary groove or recess on an adjacent unit to form a channel to receive a key to interlock the adjacent units together.

111. Apparatus of claim 110, further comprising a base and/or a lid for cooperating with the insulation liner housed within the chamber, the base and/or lid comprises carbon based materials, wherein the base and/or the lid comprises an assembly of a plurality of interlocked units.

112. Apparatus of claim 110, wherein the insulation liner is formed from two or more ring assemblies of interlocked units stacked in interlocked relationship.

113. Apparatus of claim 110, wherein the interlocking feature on at least one side comprises a tongue-like projection receivable in a complementary groove or recess in an adjacent unit.

114. Apparatus of claim 110, wherein said at least one unit comprises rigid-flexible board insulating material.
